(19) United States
(12) Patent Application Publication
(10) Pub. No.: US 2015/0253671 A1
(43) Pub. Date: Sep. 10, 2015

(54) COMPOSITION FOR PATTERN FORMATION, AND PATTERN-FORMING METHOD

(71) Applicant: JSR CORPORATION, Tokyo (JP)

(72) Inventors: Hiroyuki KOMATSU, Tokyo (JP); Shinya MINEGISHI, Tokyo (JP); Yuji NAMIE, Tokyo (JP); Tomoki NAGAI, Tokyo (JP)

(73) Assignee: JSR CORPORATION, Tokyo (JP)

(21) Appl. No.: 14/638,610

(22) Filed: Mar. 4, 2015

(30) Foreign Application Priority Data
Mar. 5, 2014 (JP) 2014-043353

(51) Int. Cl. G03F 7/20; G03F 7/038

(52) U.S. Cl. CPC G03F 7/20; G03F 7/0388; G03F 7/038

(57) ABSTRACT

A composition for pattern formation includes a polymer or a polymer set including a plurality of polymers. The polymer or the polymer set is capable of forming a phase separation structure through directed self-assembly. The polymer or at least one polymer in the polymer set includes a crosslinkable group in a side chain thereof. A pattern-forming method includes providing a directed self-assembling film on a substrate using the composition. The directed self-assembling film includes a phase separation structure.

### CROSS-REFERENCE TO RELATED APPLICATIONS

The present application claims priority to Japanese Patent Application No. 2014-043353, filed Mar. 5, 2014. The contents of this application are incorporated herein by reference in their entirety.

### BACKGROUND OF THE INVENTION

1. Field of the Invention

The present invention relates to a composition for pattern formation and a pattern-forming method.

2. Discussion of the Background

Miniaturization of various types of electronic device structures such as semiconductor devices and liquid crystal devices has been accompanied by demands for microfabrication of patterns in lithography processes. In these days, although fine patterns having a line width of about 90 nm can be formed using, for example, an ArF excimer laser beam, further finer pattern formation has been required.

To meet the demands described above, some pattern-forming methods which utilize a phase separation structure constructed through directed self-assembly, as generally referred to, that spontaneously forms an ordered pattern have been proposed. For example, an ultrafine pattern-forming method by directed self-assembly has been known in which a block copolymer obtained by copolymerizing: a monomer compound having one property; and a monomer compound having a property that is distinct from the one property is involved (see Japanese Unexamined Patent Application, Publication No. 2008-149447, Japanese Unexamined Patent Application (Translation of PCT Application), Publication No. 2002-519728, and Japanese Unexamined Patent Application, Publication No. 2003-218383). According to this method, annealing of a film formed from a composition containing the block copolymer results in a tendency of clustering of polymer structures having the same property, and thus a pattern can be formed in a self-aligning manner. In addition, a method of forming a fine pattern by permitting directed self-assembly of a composition that contains a plurality of polymers having properties that are different from one another has been also known (see U.S. Patent Application, Publication No. 2009/0214823, and Japanese Unexamined Patent Application, Publication No. 2010-58403).

### SUMMARY OF THE INVENTION

According to one aspect of the present invention, a composition for pattern formation includes a polymer or a polymer set including a plurality of polymers. The polymer or the polymer set is capable of forming a phase separation structure through directed self-assembly. The polymer or at least one polymer in the polymer set includes a crosslinkable group in a side chain thereof.

According to another aspect of the present invention, a pattern-forming method includes providing a directed self-assembling film on a substrate using the composition. The directed self-assembling film includes a phase separation structure.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings.

FIG. 1 shows a schematic cross sectional view illustrating one example of a state after providing an underlayer film on a substrate in an pattern-forming method according to an embodiment of the present invention;

FIG. 2 shows a schematic cross sectional view illustrating one example of a state after forming a prepattern on the underlayer film in the pattern-forming method according to the embodiment of the present invention;

FIG. 3 shows a schematic cross sectional view illustrating one example of a state after applying a composition for pattern formation on a region surrounded by facing walls of the prepattern on the underlayer film in the pattern-forming method according to the embodiment of the present invention;

FIG. 4 shows a schematic cross sectional view illustrating one example of a state after providing a directed self-assembling film on a region surrounded by facing walls of the prepattern on the underlayer film in the pattern-forming method according to the embodiment of the present invention; and

FIG. 5 shows a schematic cross sectional view illustrating one example of a state after removing a part of a plurality of phases of the directed self-assembling film and the prepattern in the pattern-forming method according to the embodiment of the present invention.

### DESCRIPTION OF EMBODIMENTS

The “directed self assembly” or “directed self-assembling” as referred to herein means a phenomenon of spontaneously constructing a tissue or a structure without resulting from only the control from an external factor. The term “crosslinkable group” as referred to means a group capable of forming a chemical bond to one another through a reaction under a heating condition, an active energy ray-irradiating condition, an acidic condition or the like. The term “side chain” as referred to means a chain branching from a main chain which is the longest molecular chain in a polymer.

According to an embodiment of the invention made for solving the aforementioned problems, a composition for pattern formation contains one type or a plurality of types of polymer(s) capable of forming a phase separation structure through directed self-assembly (hereinafter, may be also referred to as “(A) polymer” or “polymer (A)”), wherein at least one of the polymer(s) includes a crosslinkable group in a side chain thereof.

According to another embodiment of the invention made for solving the aforementioned problems, a pattern-forming method includes providing, on a substrate, a directed self-assembling film having a phase separation structure, wherein the directed self-assembling film is provided using the composition for pattern formation.

The composition for pattern formation and the pattern-forming method according to the embodiments of the present invention enable a pattern being sufficiently fine and having a cross-sectional shape that is superior in rectangularity (i.e., tailing of of a pattern configuration is reduced) to be formed. Therefore, these can be suitably used for lithography processes in manufacture of various types of electronic devices such as semiconductor devices and liquid crystal devices for which further miniaturization is demanded.

Hereinafter, embodiments of the composition for pattern formation and the pattern-forming method according to the present invention are explained in detail.

### Composition for Pattern Formation

A composition for pattern formation according to an embodiment of the present invention contains the polymer (A). In addition, the composition for pattern formation preferably further contains an acid generator that generates an acid upon application of an energy (hereinafter, may be also referred to as “(B) acid generator” or “acid generator (B)”). Moreover, the composition for pattern formation may contain optional component(s) such as (C) a solvent and a surfactant in addition to the polymer (A) and the acid generator (B), within a range not leading to impairment of the effects of the present invention. A pattern can be formed by applying the composition for pattern formation on a substrate to provide a film having a phase separation structure constructed through directed self-assembly (directed self-assembling film), and removing a part of a plurality of phases of the directed self-assembling film.

Hereinafter, each component is explained in detail.

### (A) Polymer

The polymer (A) includes one type or a plurality of types of polymer(s) capable of forming a phase separation structure through directed self-assembly, and at least one of the polymer(s) includes a crosslinkable group in a side chain thereof. In other words, at least one type of the polymer (A) has a structural unit that includes a crosslinkable group in a side chain thereof (hereinafter, may be also referred to as “structural unit (I)”). Since the polymer (A) includes one type or a plurality of types of polymer(s) capable of forming a phase separation structure through directed self-assembly, and at least one of the polymer(s) includes a crosslinkable group in a side chain thereof, the composition for pattern formation enables a pattern being sufficiently fine and having a cross-sectional shape that is superior in rectangularity to be formed. Although not necessarily clarified, the reason for achieving the effects described above resulting from the composition for pattern formation having the aforementioned constitution is presumed to be as in the following, for example. Specifically, due to the polymer (A) including the crosslinkable group, the polymer molecules would be crosslinked within phases formed by the composition for pattern formation, and crosslinking would also occur between the polymer (A) and the underlayer film and/or the like. Thus, etching resistance would be improved, whereby a pattern that is fine and has a cross-sectional shape that is superior in rectangularity would be more conveniently formed.

The polymer (A) may have, in addition to the structural unit (I), a structural unit (II) that includes an acid-labile group, as well as a structural unit (III) that includes at least one selected from the group consisting of a lactone structure, a cyclic carbonate structure and a sultone structure. Moreover, the polymer (A) may have a structural unit other than the structural units (I) to (III). The polymer (A) may have one, or two or more types of each of the above structural units.

Hereinafter, each structural unit is explained.

### Structural Unit (I)

The structural unit (I) includes a crosslinkable group. It is considered that since the polymer (A) includes the structural unit (I), at least a part of a plurality of phases are crosslinked, leading to an improvement of the etching resistance of these phases, and consequently, rectangularity of the cross-sectional shape of the pattern can be further improved.

Examples of the crosslinkable group include:

groups that has a reactive unsaturated double bond, such as a vinyl group, a vinyl ether group and a (meth)acryloyl group;

ring-opening polymerization reactive groups, e.g., cyclic ether groups such as an oxiranyl group, an oxetanyl group and a tetrahydrofurfuryl group;

groups having active hydrogen such as a hydroxyl group, a methylol group, a carboxy group, an amino group, a phenolic hydroxyl group, a mercapto group, a hydrosilyl group and a silanol group;

groups that include a group which can be substituted with a nucleophile, such as an active halogen atom-containing group, a sulfonic acid ester group and a carbamoyl group;

acid anhydride groups; and the like.

Of these, as the crosslinkable group, a group that has a reactive unsaturated double bond, and a cyclic ether group are preferred, a vinyl group, a vinyl ether group, an oxiranyl group, an oxetanyl group and a tetrahydrofurfuryl group are more preferred, and a vinyl group is still more preferred.

In a case where the polymer (A) includes one type of polymer, the lower limit of the proportion of the structural unit (I) with respect to the total structural units constituting the polymer (A) is preferably 2 mol %, more preferably 5 mol %, and still more preferably 10 mol %. The upper limit of the proportion is preferably 60 mol %, more preferably 55 mol %, and still more preferably 50 mol %.

In a case where the polymer (A) includes a plurality of types of polymers, the lower limit of the proportion of the structural unit (I) in the polymer that includes a crosslinkable group among the plurality of types of polymers, with respect to the total structural units constituting the polymer that includes a crosslinkable group is preferably 10 mol %, more preferably 20 mol %, and still more preferably 30 mol %. The upper limit of the proportion is preferably 100 mol %, more preferably 70 mol %, and still more preferably 60 mol %.

When the proportion of the structural unit (I) falls within the above range, the etching resistance in the phases remaining after the etching of the polymer (A) can be further improved and as a result, the rectangularity of the pattern is further improved.

### Structural Unit (II)

The structural unit (II) includes an acid-labile group. When the polymer (A) includes the structural unit (II), the hydrophilicity of the polymer (A) is improved upon dissociation of the acid-labile group by an acid to generate a carboxy group or the like. Thus, phases that can be readily etched are formed in the polymer (A), and consequently a favorable pattern that is superior in rectangularity of the cross-sectional shape can be obtained.

As the structural unit (II), a structural unit represented by the following formula (1-1) or (1-2) (hereinafter, may be also referred to as “structural unit (II-1) or (II-2)”) is preferred. In the following formulae (1-1) and (1-2), the group represented by —CR^{p1}R^{p2}R^{p3} or —CR^{p4}R^{p5}R^{p6} is an acid-labile group.

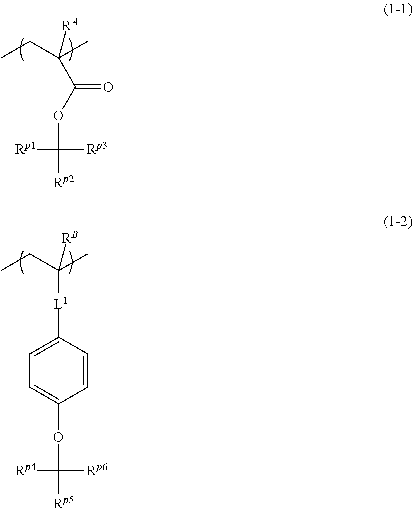

In the above formula (1-1), R^{p1} represents a monovalent hydrocarbon group having 1 to 20 carbon atoms; R^{p2} and R^{p3} each independently represent a monovalent chain hydrocarbon group having 1 to 20 carbon atoms or a monovalent alicyclic hydrocarbon group having 3 to 20 carbon atoms, or R^{p2} and R^{p3} taken together represent an alicyclic structure having 3 to 20 ring atoms together with the carbon atom to which R^{p2} and R^{p3} bond; and R^{A} represents a hydrogen atom, a fluorine atom, a methyl group or a trifluoromethyl group.

In the formula (1-2), R^{p4}, R^{p5} and R^{p6} each independently represent a monovalent hydrocarbon group having 1 to 20 carbon atoms or a monovalent oxyhydrocarbon group having 1 to 20 carbon atoms; L¹ represents a single bond, —O—, —COO— or —CONN—; and R^{B} represents a hydrogen atom, a fluorine atom, a methyl group or a trifluoromethyl group.

Examples of the monovalent hydrocarbon group having 1 to 20 carbon atoms represented by R^{p1}, R^{p4}, R^{p5} and R^{p6} include:

chain hydrocarbon groups such as:
alkyl groups such as a methyl group, an ethyl group, a propyl group and a butyl group;
alkenyl groups such as an ethenyl group, a propenyl group and a butenyl group; and
alkynyl groups such as an ethynyl group, a propynyl group and a butynyl group;

alicyclic hydrocarbon groups such as:
cycloalkyl groups such as a cyclopropyl group, a cyclopentyl group, a cyclohexyl group, a norbornyl group and an adamantyl group; and
cycloalkenyl groups such as a cyclopropenyl group, a cyclopentenyl group, a cyclohexenyl group and a norbornenyl group;

aromatic hydrocarbon groups such as:
aryl groups such as a phenyl group, a tolyl group, a xylyl group, a naphthyl group and an anthryl group; and
aralkyl groups such as a benzyl group, a phenethyl group and a naphthylmethyl group; and the like.

As R^{p1}, a chain hydrocarbon group, and a cycloalkyl group are preferred, an alkyl group and a cycloalkyl group are more preferred, and a methyl group, an ethyl group, a propyl group, a cyclopentyl group, a cyclohexyl group, a cyclooctyl group, an adamantyl group are still more preferred.

Examples of the monovalent chain hydrocarbon group having 1 to 20 carbon atoms which may be represented by R^{p2} and R^{p3} include chain hydrocarbon groups among the groups exemplified as the monovalent hydrocarbon group represented by R^{p1}, and the like.

Examples of the monovalent alicyclic hydrocarbon group having 3 to 20 carbon atoms which may be represented by R^{p2} and R^{p3} include:

saturated monocyclic hydrocarbon groups such as a cyclopropyl group, a cyclobutyl group, a cyclopentyl group, a cyclohexyl group, a cyclopentyl group, a cyclooctyl group, a cyclodecyl group and a cyclododecyl group;

unsaturated monocyclic hydrocarbon groups such as a cyclopropenyl group, a cyclobutenyl group, a cyclopentenyl group, a cyclohexenyl group, a cyclooctenyl group and a cyclodecenyl group;

saturated polycyclic hydrocarbon groups such as a bicyclo[2.2.1]heptanyl group, a bicyclo[2.2.2]octanyl group and a tricyclo[3.3.1.1^{3,7}]decanyl group;

unsaturated polycyclic hydrocarbon groups such as a bicyclo[2.2.1]heptenyl group and a bicyclo[2.2.2]octenyl group; and the like.

Examples of the alicyclic structure having 3 to 20 ring atoms taken together represented by R^{p2} and R^{p3} together with the carbon atom to which R^{p2} and R^{p3} bond include:

monocyclic cycloalkane structures such as a cyclopropane structure, a cyclobutane structure, a cyclopentane structure, a cyclopentene structure, a cyclopentadiene structure, a cyclohexane structure, a cyclooctane structure and a cyclodecane structure;

polycyclic cycloalkane structures such as a norbornane structure, an adamantane structure, a tricyclodecane structure and a tetracyclododecane structure; and the like.

As R^{p2} and R^{p3}, an alkyl group; a monocyclic cycloalkane structure, a norbornane structure and an adamantane structure each taken together represented by R^{p2} and R^{p3} are preferred, and a methyl group; an ethyl group; a cyclopentane structure; a cyclohexane structure; and an adamantane structure are more preferred.

Examples of the monovalent oxyhydrocarbon group having 1 to 20 carbon atoms which may be represented by R^{p4}, R^{p5} and R^{p6} include the monovalent hydrocarbon group having 1 to 20 carbon atoms exemplified in connection with R^{p1}, R^{p4}, R^{p5} and R^{p6} in which an oxygen atom is included between carbon atoms, and the like.

As R^{p4}, R^{p5} and R^{p6}, a chain hydrocarbon group and an alicyclic hydrocarbon group including an oxygen atom are preferred.

L¹ represents preferably a single bond or —COO—, and more preferably a single bond.

R^{A} represents preferably a hydrogen atom or a methyl group, and more preferably a methyl group, in light of copolymerizability of a monomer that gives a structural unit (II).

R^{B} represents preferably a hydrogen atom and a methyl group, and more preferably a hydrogen atom, in light of copolymerizability of a monomer that gives a structural unit (II).

Examples of the structural unit (II-1) include the structural units represented by the following formulae (1-1-a) to (1-1-d) (hereinafter, may be also referred to as “structural units (II-1-a) to (II-1-d)”), and the like.

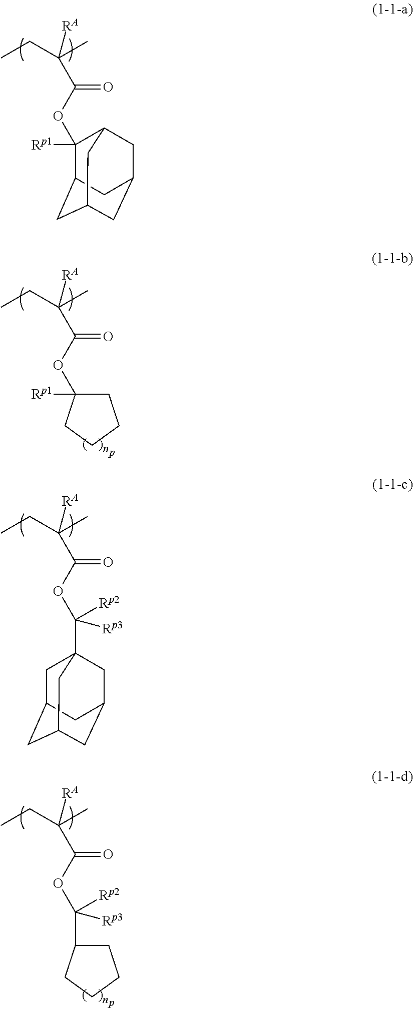

In the above formulae (1-1-a) to (1-1-d), R^{A} and R^{p1} to R^{p3} are as defined in the above formula (1-1); and nₚ is an integer of 1 to 4.

Preferably nₚ is 1, 2 or 4, and more preferably 1.

Examples of the structural unit (II-1) include structural units represented by the following formulae, and the like.

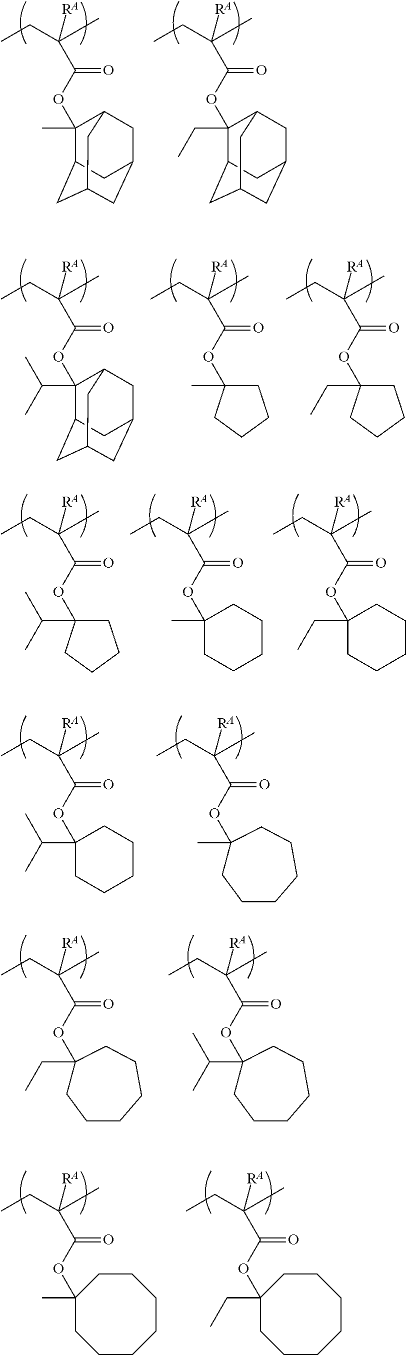

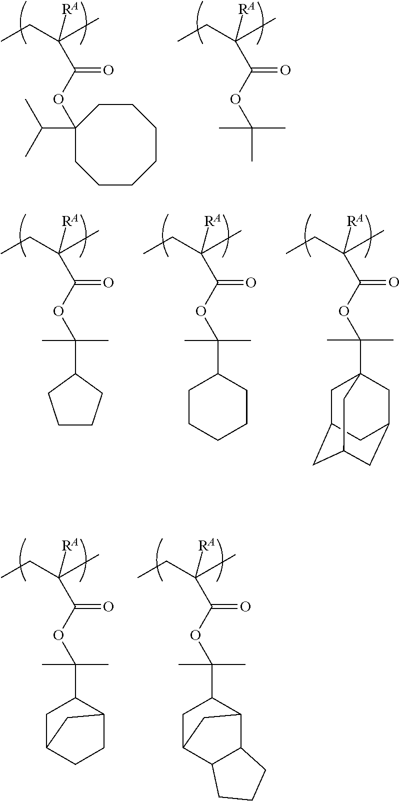

In the above formulae, R^{A} is as defined in the above formula (2-1).

Examples of the structural unit (II-2) include the structural units represented by the following formulae (1-2-1) to (1-2-8) (hereinafter, may be also referred to as “structural units (II-2-1) to (II-2-8)”), and the like.

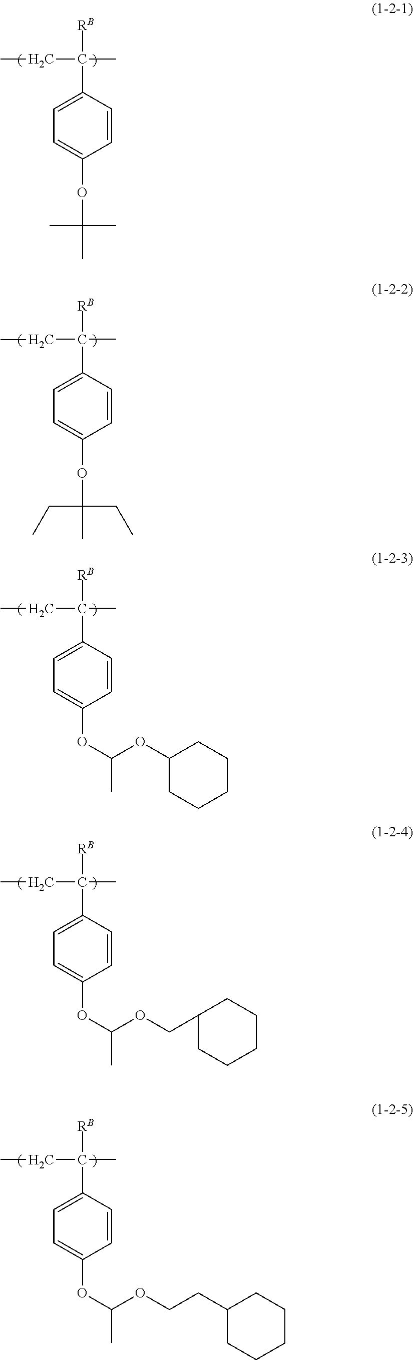

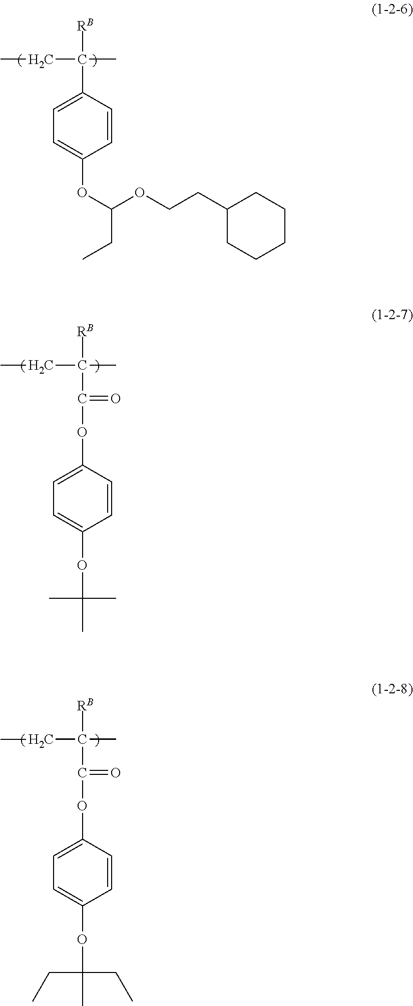

In the above formulae, R^{B} is as defined in the above formula (1-2).

As the structural unit (II), the structural units (II-1-1) to (II-1-4), (II-2-1), and (II-2-5) are preferred, and a structural unit derived from 2-methyl-2-adamantyl(meth)acrylate, a structural unit derived from 2-i-propyl-2-adamantyl(meth)acrylate, a structural unit derived from 1-methyl-1-cyclopentyl(meth)acrylate, a structural unit derived from 1-ethyl-1-cyclohexyl(meth)acrylate, a structural unit derived from 1-i-propyl-1-cyclopentyl(meth)acrylate, a structural unit derived from 2-cyclohexyl propan-2-yl(meth)acrylate, a structural unit derived from 2-(adamantan-1-yl)propan-2-yl(meth)acrylate, and a structural unit (II-2-1) are more preferred.

In a case where the polymer (A) includes one type of polymer, the lower limit of the proportion of the structural unit (II) with respect to the total structural units constituting the polymer (A) is preferably 0 mol %, more preferably 5 mol %, and still more preferably 15 mol %. The upper limit of the proportion is preferably 70 mol %, more preferably 60 mol %, and still more preferably 50 mol %.

In a case where the polymer (A) includes a plurality of types of polymers, the proportion of the structural unit (II) in the polymer that includes a crosslinkable group among the plurality of types of polymers, with respect to the total structural units constituting the polymer that includes a crosslinkable group is preferably no greater than 10 mol %, more preferably no greater than 5 mol %, and still more preferably 0 mol %.

The lower limit of the proportion of the structural unit (II) in the polymer that does not include a crosslinkable group among the plurality of types of polymers, with respect to the total structural units constituting the polymer that does not include a crosslinkable group is preferably 0 mol %, more preferably 5 mol %, and still more preferably 10 mol %. The upper limit of the proportion is preferably 100 mol %, more preferably 70 mol %, and still more preferably 60 mol %.

When the proportion of the structural unit (II) falls within the above range, a more appropriate difference in terms of hydrophilicity between the phases may be achieved after the dissociation of the acid-labile group of the polymer (A), and consequently a finer pattern can be obtained and the rectangularity of the pattern may be also improved.

### Structural Unit (III)

The structural unit (III) includes at least one selected from the group consisting of a lactone structure, a cyclic carbonate structure and a sultone structure. When the polymer (A) further has the structural unit (III) in addition to the structural unit (I), the polymer (A) may have appropriate polarity. As a result, the composition for pattern formation enables a pattern being finer and having a cross-sectional shape that is superior in rectangularity to be formed. The lactone structure as referred to herein means a structure having a ring (lactone ring) that includes a group represented by —O—C(O)—. In addition, the cyclic carbonate structure as referred to means a structure having a ring (cyclic carbonate ring) that includes a group represented by —O—C(O)—O—. The sultone structure as referred to means a structure having a ring (sultone ring) that includes a group represented by —O—S(O)₂—.

Examples of the structural unit (III) include structural units represented by the following formulae, and the like.

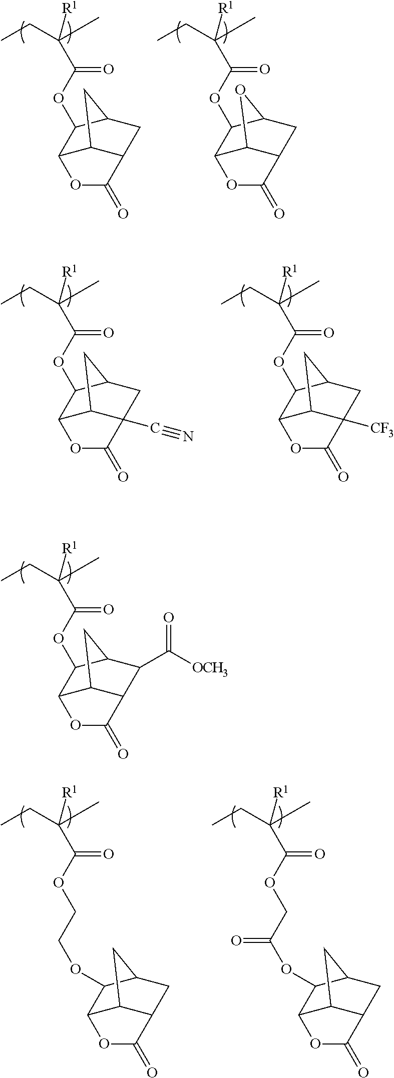

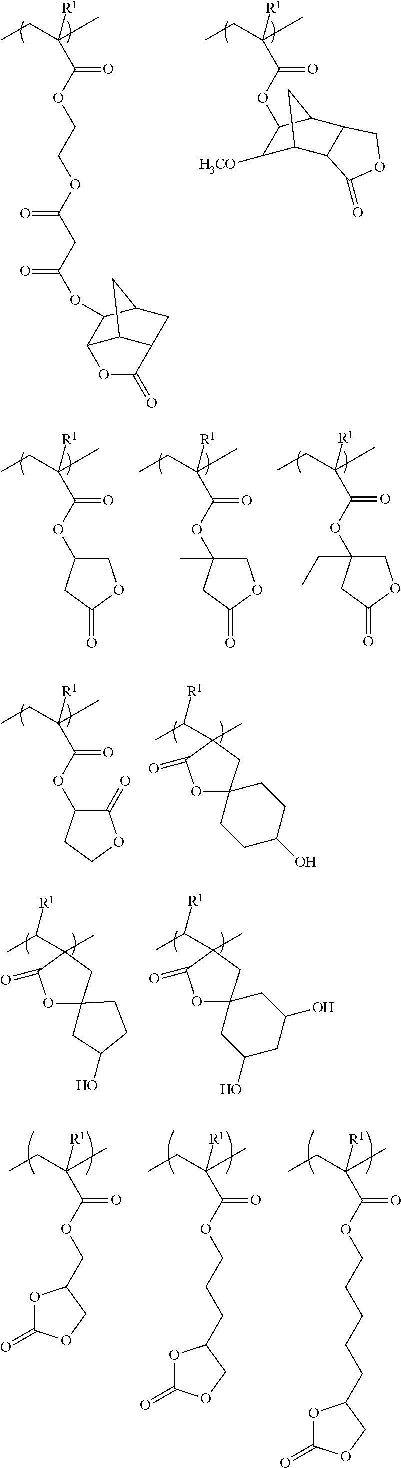

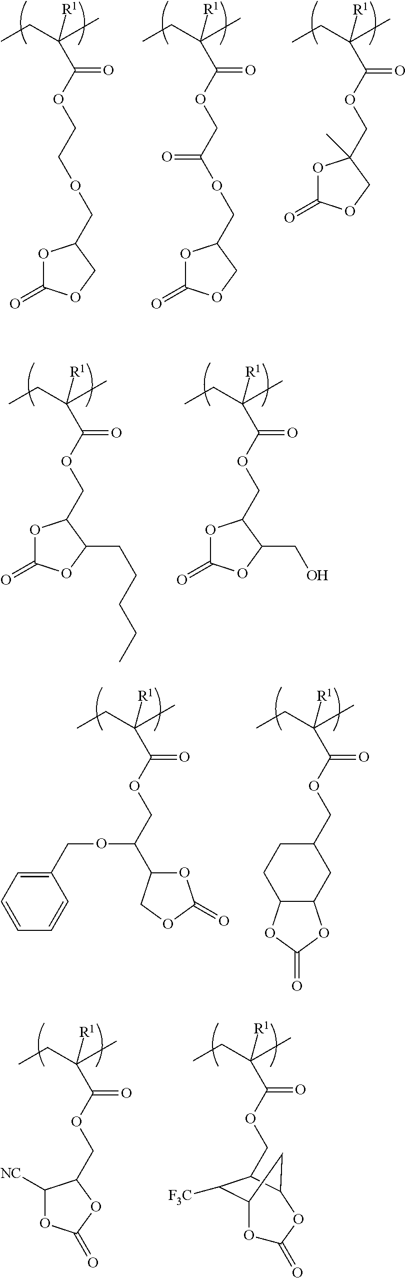

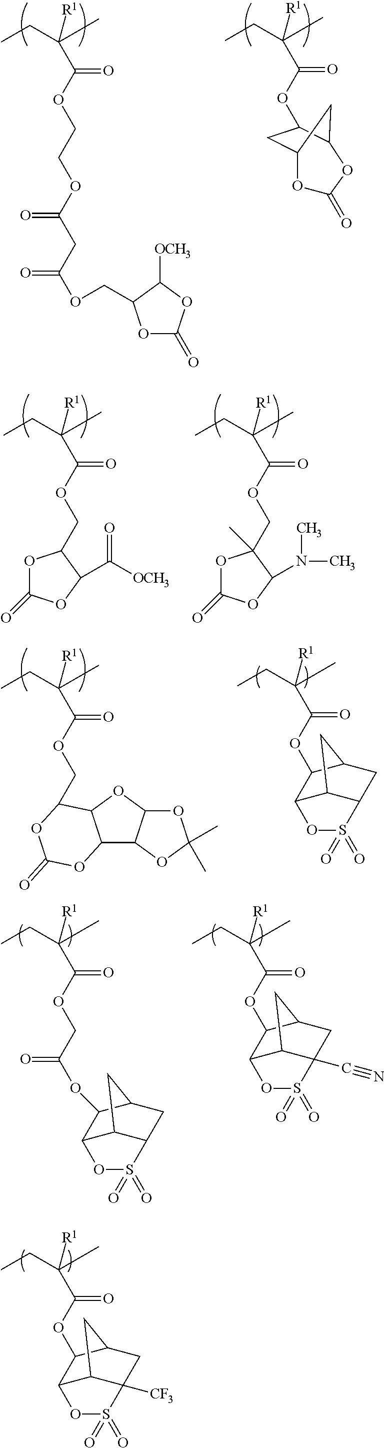

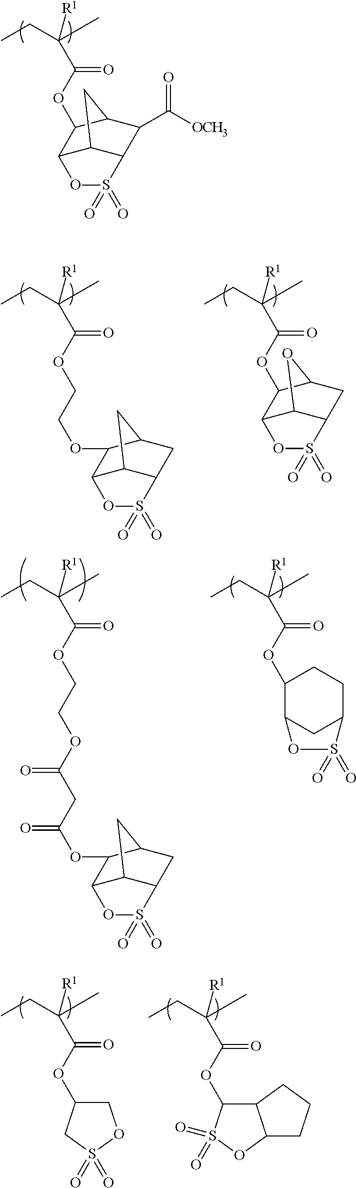

In the above formulae, R¹ represents a hydrogen atom, a fluorine atom, a methyl group or a trifluoromethyl group.

As R¹, a hydrogen atom and a methyl group are preferred, and a methyl group is more preferred in light of copolymerizability of a monomer that gives a structural unit (III).

Of these, as the structural unit (III), a structural unit that includes a norbornanelactone structure, a structural unit that includes an oxanorbornanelactone structure, a structural unit that includes a γ-butyrolactone structure, a structural unit that includes an ethylene carbonate structure and a structural unit that includes a norbornanesultone structure are preferred, and a structural unit derived from norbornanelacton-yl(meth)acrylate, a structural unit derived from oxanorbornanelacton-yl(meth)acrylate, a structural unit derived from cyano-substituted norbornanelacton-yl(meth)acrylate, a structural unit derived from norbornanelacton-yloxycarbonylmethyl(meth)acrylate, a structural unit derived from butyrolacton-3-yl(meth)acrylate, a structural unit derived from butyrolacton-4-yl(meth)acrylate, a structural unit derived from 3,5-dimethylbutyrolacton-3-yl(meth)acrylate, a structural unit derived from 4,5-dimethylbutyrolacton-4-yl(meth)acrylate, a structural unit derived from 1-(butyrolacton-3-yl)cyclohexan-1-yl(meth)acrylate, a structural unit derived from ethylene carbonate-ylmethyl(meth)acrylate, a structural unit derived from cyclohexenecarbonate-ylmethyl(meth)acrylate, a structural unit derived from norbornanesultone-yl(meth)acrylate, and a structural unit derived from norbornanesultone-yloxycarbonylmethyl(meth)acrylate are more preferred.

In a case where the polymer (A) includes one type of polymer, the lower limit of the proportion of the structural unit (III) with respect to the total structural units constituting the polymer (A) is preferably 0 mol %, more preferably 5 mol %, and still more preferably 10 mol %. The upper limit of the proportion is preferably 40 mol %, more preferably 30 mol %, and still more preferably 25 mol %.

In a case where the polymer (A) includes a plurality of types of polymers, the lower limit of the proportion of the structural unit (III) in the polymer that includes a crosslinkable group among the plurality of types of polymers, with respect to the total structural units constituting the polymer that includes a crosslinkable group is preferably 0 mol %, more preferably 5 mol %, and still more preferably 10 mol %. The upper limit of the proportion is preferably 70 mol %, more preferably 60 mol %, and still more preferably 50 mol %.

The lower limit of the proportion of the structural unit (III) in the polymer that does not include a crosslinkable group among the plurality of types of polymers, with respect to the total structural units constituting the polymer that does not include a crosslinkable group is preferably 0 mol %, more preferably 5 mol %, and still more preferably 10 mol %. The upper limit of the proportion is preferably 100 mol %, more preferably 70 mol %, and still more preferably 60 mol %.

When the proportion of the structural unit (III) falls within the above range, the polymer (A) may have a more appropriate polarity. When the proportion is less than the lower limit, the polymer (A) may be less likely to have a more appropriate polarity. When the proportion exceeds the upper limit, a pattern being fine and having a cross-sectional shape that is superior in rectangularity may be less likely to be formed.

### Other Structural Unit

The polymer (A) may have other structural unit in addition to the structural units (I), (II) and (III). The other structural unit is exemplified by a structural unit that includes a hydrocarbon group, and the like.

The hydrocarbon group is preferably a chain hydrocarbon group or an alicyclic hydrocarbon group, more preferably an alkyl group and a cycloalkyl group, still more preferably a methyl group, an ethyl group, a cycloalkyl group and an adamantyl group, and particularly preferably a methyl group and an adamantyl group.

In a case where the polymer (A) includes one type of polymer, the lower limit of the proportion of the other structural unit with respect to the total structural units constituting the polymer (A) is preferably 0 mol %, more preferably 5 mol %, and still more preferably 10 mol %. The upper limit of the proportion is preferably 60 mol %, more preferably 55 mol %, and still more preferably 50 mol %.

In a case where the polymer (A) includes a plurality of types of polymers, the proportion of the other structural unit in the polymer that includes an acid-labile group among the plurality of types of polymers, with respect to the total structural units constituting the polymer that includes an acid-labile group is preferably 0 mol %, more preferably 5 mol %, and still more preferably 10 mol %. The upper limit of the proportion is preferably 60 mol %, more preferably 55 mol %, and still more preferably 50 mol %.

The lower limit of the proportion of the structural unit (III) in the polymer that does not include an acid-labile group among the plurality of types of polymers, with respect to the total structural units constituting the polymer that does not include an acid-labile group is preferably 0 mol %, more preferably 5 mol %, and still more preferably 10 mol %. The upper limit of the proportion is preferably 100 mol %, more preferably 70 mol %, and still more preferably 60 mol %.

It is preferred that the polymer (A) includes only one type of block copolymer (hereinafter, may be also referred to as “(A1) block copolymer” or “block copolymer (A1)”). Moreover, it is also preferred that the polymer (A) includes a plurality of types of polymers (hereinafter, may be also referred to as “(A2) polymer” or “polymer” (A2)).

### (A1) Block Copolymer

The block copolymer (A1) is constituted with a plurality of types of blocks, and at least one type of the plurality of types of blocks includes a crosslinkable group. Each block has a chain structure having units derived from one type or a plurality of types of monomers, and monomers constituting each block are different from each other. When the block copolymer (A1) including such a plurality of blocks is dissolved in an appropriate solvent, the same type of blocks are aggregated, and thus phases each configured with the same type of the block are formed. In this process, it is presumed that a phase separation structure having an ordered pattern in which different types of phases are periodically and alternately repeated can be formed since the phases formed with different types of the blocks are unlikely to be admixed with each other.

The block constituting the block copolymer (A1) is exemplified by a poly(meth)acrylate block, a polystyrene block, a polyvinyl acetal block, a polyurethane block, a polyurea block, a polyimide block, a polyamide block, an epoxy block, a novolak-type phenol block, a polyester block, and the like. Of these, in light of the possibility of forming a pattern having a finer microdomain structure, it is preferred that the block copolymer (A1) has a polystyrene block and a poly(meth)acrylate block, and it is more preferred that the block copolymer (A1) is constituted with only a polystyrene block and a poly(meth)acrylate block.

The block including a crosslinkable group is exemplified by a block that includes the group exemplified in connection with the structural unit (I) in a side chain thereof.

It is preferred that only one type of the plurality of types of blocks constituting the block copolymer (A1) is the block including a crosslinkable group. When only one type of block thus includes the crosslinkable group, a crosslinking reaction occurs principally within phases formed from one type of block, leading to efficient orientation of the block. In addition, due to the phases formed from the block exhibiting superior etching resistance, other phases formed from other block are relatively more readily etched. Consequently, a pattern that is finer and superior in rectangularity can be formed.

Moreover, in a case where the block copolymer (A1) has a polystyrene block, it is preferred that the polystyrene block alone includes a crosslinkable group, whereas other type of block does not include a crosslinkable group. The polystyrene block exhibits superior etching resistance as compared with a poly(meth)acrylate block and the like. Furthermore, the etching resistance of the phases formed from the polystyrene block is further improved due to the presence of the crosslinkable group. As a result, the rectangularity of the cross-sectional shape of the pattern is further improved.

The block copolymer (A1) may have each of blocks constituted with the structural units (II) and (III) and other structural unit, respectively, in addition to the block constituted with the structural unit (I). When the block constituted with the structural unit (II) is thus further included in addition to the block constituted with the structural unit (I), the rectangularity of the cross-sectional shape of the pattern may be further improved, since the phases formed from the block including a crosslinkable group become less likely to be etched, whereas the phases formed from the block including an acid-labile group become more likely to be readily etched.

Examples of the block including an acid-labile group other than the polystyrene block and the poly(meth)acrylate block include blocks including in a side chain thereof, a group represented by: —O—CR^{p1}R^{p2}R^{p3} and —O—CR^{p4}R^{p5}R^{p6} in the above formulae (1-1) and (1-2).

In a case where the block copolymer (A1) is constituted from only the polystyrene block and the poly(meth)acrylate block, the molar ratio of the styrene unit to the (meth)acrylic acid ester unit in the block copolymer (A1) is preferably no less than no less than 10/90 and no greater than 90/10, more preferably no less than 20/80 and no greater than 80/20, and still more preferably no less than 30/70 and no greater than 70/30. When the ratio of the proportion of the styrene unit (mol %) to the proportion of the (meth)acrylic acid ester unit (mol %) in the block copolymer (A1) falls within the above specified range, the composition for pattern formation enables a pattern that is even finer and has a favorable microdomain structure to be formed.

The block copolymer (A1) is exemplified by a diblock copolymer, a triblock copolymer, a tetrablock copolymer, and the like. Of these, in light of a possibility of easy formation of a pattern having a desired fine microdomain structure, the diblock copolymer and the triblock copolymer are preferred, and the diblock copolymer is more preferred.

### Synthesis Method of Block Copolymer (A1)

The block copolymer (A1) may be synthesized through living cationic polymerization, living anionic polymerization, living radical polymerization or the like, and for example, the block copolymer (A1) may be synthesized by linking while polymerizing the polystyrene block, the poly(meth)acrylate block and the other block(s) in a desired order. Of these, in light of an improvement of the rectangularity of the cross-sectional shape of the pattern, living anionic polymerization is more preferred.

For example, in a case where the block copolymer (A1) that is a diblock copolymer constituted with the polystyrene block and the poly(meth)acrylate block is to be synthesized, styrene is polymerized first using an anion polymerization initiator in an appropriate solvent to form a polystyrene block. Next, a (meth)acrylic acid ester is similarly added, which is linked to the polystyrene block, whereby a poly(meth)acrylate block is formed. It is to be noted that in regard to the synthesis method of each block, for example, the synthesis can be executed by a process including e.g., adding a solution containing a monomer dropwise into a reaction solvent containing an initiator to permit a polymerization reaction.

Examples of the solvent for use in the polymerization include:

alkanes such as n-pentane, n-hexane, n-heptane, n-octane, n-nonane and n-decane;

cycloalkanes such as cyclohexane, cycloheptane, cyclooctane, decalin and norbornane;

aromatic hydrocarbons such as benzene, toluene, xylene, ethylbenzene and cumene;

halogenated hydrocarbons such as chlorobutanes, bromohexanes, dichloroethanes, hexamethylene dibromide and chlorobenzene;

saturated carboxylic acid esters such as ethyl acetate, n-butyl acetate, i-butyl acetate and methyl propionate;

ketones such as acetone, 2-butanone, 4-methyl-2-pentanone, 2-heptanone and cyclohexanone;

ethers such as tetrahydrofuran, dimethoxyethanes and diethoxyethanes; and the like. These solvents may be used either alone, or two or more types thereof may be used in combination.

The reaction temperature in the polymerization may be predetermined ad libitum depending on the type of the initiator, and is typically −150° C. to 50° C. and preferably −80° C. to 40° C. The reaction time period is typically 5 min to 24 hrs, and preferably 20 min to 12 hrs.

Examples of the initiator for use in the polymerization include alkyllithiums, alkylmagnesium halides, naphthalene sodium, alkylated lanthanoid compounds, and the like. Of these, an alkyllithium compound is preferably used in a case where the polymerization is carried out using styrene or methyl methacrylate as a monomer.

The block copolymer (A1) is preferably recovered through a reprecipitation procedure. More specifically, after completion of the reaction, the intended copolymer is recovered in the form of a powder through charging the reaction liquid into a reprecipitation solvent. As the reprecipitation solvent, an alcohol, an alkane and the like may be used either alone or as a mixture of two or more types thereof. Alternative to or in addition to the reprecipitation procedure, a liquid separating operation, a column operation, an ultrafiltration operation or the like also enables the polymer to be recovered through eliminating low molecular components such as monomers and oligomers.

The weight average molecular weight (Mw) of the block copolymer (A1) as determined by gel permeation chromatography (GPC) is preferably 5,000 to 80,000, more preferably 8,000 to 70,000, and still more preferably 10,000 to 50,000. When the Mw of the block copolymer (A1) falls within such a specific range, the composition for pattern formation enables a pattern that is finer and has a favorable microdomain structure to be formed.

The ratio (Mw/Mn) of the Mw to the number average molecular weight (Mn) of the block copolymer (A1) is typically 1 to 5, preferably 1 to 3, more preferably 1 to 2, still more preferably 1 to 1.5, and particularly preferably 1 to 1.2. When the Mw/Mn falls within such a specific range, the composition for pattern formation enables a pattern that is finer and has a favorable microdomain structure to be formed.

It is to be noted that the Mw and the Mn are determined by gel permeation chromatography (GPC) using GPC columns (“G2000 HXL”×2, “G3000 HXL”×1, and “G4000 HXL”×1; all manufactured by Tosoh Corporation), a differential refractometer as a detector, and mono-dispersed polystyrene as a standard, under the analytical conditions involving: flow rate of 1.0 mL/min; an elution solvent of tetrahydrofuran; a sample concentration of 1.0% by mass; an amount of the sample injected of 100 μm; and a column temperature of 40° C.

### (A2) Polymer

The polymer (A2) includes a plurality of types of polymers, and at least one type of the plurality of types of polymers includes a crosslinkable group. Monomers constituting each polymer are different from each other. When the polymer (A2) including such a plurality of types of polymers is dissolved in an appropriate solvent, the same type of blocks are aggregated, and thus phases each configured with the same type of the polymer are formed. In this process, it is presumed that a phase separation structure having an ordered pattern in which different types of phases are periodically and alternately repeated can be formed since the phases formed with different types of the blocks are unlikely to be admixed with each other.

The polymer constituting the polymer (A2) is exemplified by an acrylic polymer, a styrene polymer, a vinyl acetal polymer, a urethane polymer, a urea polymer, an imide polymer, an amide polymer, a novolak-type phenol polymer, an ester polymer, and the like. It is to be noted that the polymer may be either a homopolymer synthesized from one type of a monomer compound, or a copolymer synthesized from a plurality of types of monomer compounds. It is preferred that the polymer (A2) includes a styrene polymer and an acrylic polymer, and it is more preferred that the polymer (A2) includes only a styrene polymer and an acrylic polymer.

The polymer that includes a crosslinkable group is exemplified by a polymer that includes in a side chain thereof the group exemplified in connection with the structural unit (I).

It is preferred that only one type of the polymer (A2) is the polymer that includes a crosslinkable group. When only one type of polymer thus includes a crosslinkable group, a crosslinking reaction occurs predominantly in phases formed from the one type of polymer; therefore, the polymer can be efficiently oriented. In addition, due to superior etching resistance of the phases formed from the polymer, other phases formed from the other polymer become relatively easily etched. As a result, a pattern that is finer and more superior in rectangularity can be formed.

In addition, in a case where the polymer (A2) has a styrene polymer, it is preferred that the styrene polymer alone includes a crosslinkable group, whereas other type of polymer does not include a crosslinkable group. The styrene polymer has more superior etching resistance as compared with the acrylic polymer and the like. Moreover, owing to the presence of the crosslinkable group, the etching resistance of the phases formed from the styrene polymer can be improved. Consequently, the rectangularity of the cross-sectional shape of the pattern is further improved.

The polymer (A2) may include the structural units (II) and (III), and other structural unit. In this case, it is preferred that the crosslinkable group and the structural unit (II) are included in distinct polymers. When the crosslinkable group and the acid-labile group are thus included in distinct polymers, the phases formed from the polymer that includes a crosslinkable group are hardly etched, whereas the phases formed from the polymer that includes an acid-labile group are readily etched; therefore, the rectangularity of the cross-sectional shape of the pattern can be further improved.

Examples of the polymer that includes an acid-labile group other than the styrene polymer and the acrylic polymer include polymers including in a side chain thereof, a group represented by: —O—CR^{p1}R^{p2}R^{p3} and —O—CR^{p4}R^{p5}R^{p6} in the above formulae (1-1) and (1-2).

In a case where the polymer (A2) is constituted from only the styrene block polymer and the acrylic polymer, the molar ratio of the styrene polymer to the acrylic polymer in the polymer (A2) is preferably no less than no less than 10/90 and no greater than 90/10, more preferably no less than 20/80 and no greater than 80/20, and still more preferably no less than 30/70 and no greater than 70/30. When the ratio of the proportion of the styrene polymer (mol %) to the proportion of the acrylic polymer in the polymer (A2) falls within the above specified range, the composition for pattern formation enables a pattern that is even finer and has a favorable microdomain structure to be formed.

### Synthesis Method of Block Copolymer (A2)

Each polymer in the polymer (A2) may be synthesized through polymerization of, for example, a monomer corresponding to each given structural unit using a polymerization initiator such as a radical polymerization initiator in an appropriate polymerization reaction solvent. For example, the polymer (A2) is preferably synthesized by a method such as: a method in which a solution containing a monomer and a radical polymerization initiator is added dropwise into a solution containing a polymerization reaction solvent or a monomer to permit a polymerization reaction; a method in which a solution containing a monomer, and a solution containing a radical polymerization initiator are each separately added dropwise into a solution containing a polymerization reaction solvent or a monomer to permit a polymerization reaction; or a method in which a plurality of types of solutions containing each of monomers, and a solution containing a radical polymerization initiator are each separately added dropwise into a solution containing a polymerization reaction solvent or a monomer to permit a polymerization reaction.

Examples of the radical polymerization initiator include: azo radical initiators such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile) and dimethyl 2,2′-azobisisobutyrate; peroxide radical initiators such as benzoyl peroxide, t-butyl hydroperoxide and cumene hydroperoxide; and the like. Of these, AIBN and dimethyl 2,2′-azobisisobutyrate are preferred, and AIBN is more preferred. These radical polymerization initiators may be used either alone, or as a mixture of two or more types thereof.

As the solvent for use in the polymerization, for example, those similar to the solvent.

The reaction temperature in the polymerization is typically 40° C. to 150° C., and preferably 50° C. to 120° C. The reaction time period is typically 1 hour to 48 hrs, and preferably 1 hour to 24 hrs.

It is preferred that the polymer obtained through the polymerization reaction is recovered by a reprecipitation technique similarly to the block copolymer (A1). Also, the reprecipitation solvent and other method which may be employed for recovering the polymer are similar to those in the case of the block copolymer (A1).

Although the polystyrene equivalent weight average molecular weight (Mw) of each polymer included in the polymer (A2) as determined by gel permeation chromatography (GPC) is not particularly limited the Mw is preferably no less than 3,000 and no greater than 50,000, more preferably no less than 5,000 and no greater than 30,000, still more preferably no less than 7,000 and no greater than 20,000, and particularly preferably no less than 8,000 and no greater than 15,000. When the Mw of the polymer falls within the above range, an even finer pattern may be obtained from the composition for pattern formation, and also the rectangularity of the pattern is improved. When the Mw of the polymer is less than the lower limit described above, heat resistance of the directed self-assembling film may be deteriorated. When the Mw of the polymer is greater than the upper limit described above, a sufficiently fine pattern may not be obtained.

The ratio (Mw/Mn) of the Mw to the polystyrene equivalent number average molecular weight (Mn) of each polymer in the polymer (A2) as determined on GPC is typically no less than 1 and no greater than 5, preferably 1 no less than and no greater than 3, and still more preferably no less than 1 and no greater than 2.

### (B) Acid Generator

The acid generator (B) is a compound that generates an acid upon application of an energy. An action of this acid allows a crosslinking reaction of the polymer (A) by way of the crosslinkable group to be accelerated. In addition, in a case where the polymer (A) has an acid-labile group, the acid-labile group is dissociated, thereby giving a polar group such as a carboxy group. As a result, the etching rate of the polymer (A) is altered. Exemplary application methods of the energy involve exposure, heating, and the like. The acid generator (B) may be contained either in the form of a compound as described later (hereinafter, may be referred to as “acid generating agent (B)” ad libitum), or in the form incorporated as a part of the polymer, or may be in both of these forms.

The acid generating agent (B) is exemplified by an onium salt compound, an N-sulfonyloxyimide compound, a halogen-containing compound, a diazo ketone compound, and the like.

Examples of the onium salt compound include sulfonium salts, iodonium salts, tetrahydrothiophenium salts, phosphonium salts, diazonium salts, pyridinium salts, and the like.

Specific examples of the acid generating agent (B) that generates an acid upon exposure (hereinafter, may be also referred to as “(B1) photoacid generating agent” or “photoacid generating agent (B1)”) include the compounds disclosed in paragraphs [0080] to [0113] of Japanese Unexamined Patent Application, Publication No. 2009-134088, for example, and the like.

In addition, examples of the acid generating agent (B) that generates an acid by heating (hereinafter, may be also referred to as “(B2) thermal acid generating agent” or “thermal acid generating agent (B2)”) include the onium salt-type acid generating agents exemplified as the photoacid generating agent (B1) described above, as well as 2,4,4,6-tetrabromocyclohexadienone, benzoin tosylate, 2-nitrobenzyl tosylate, alkylsulfonates, and the like.

It is preferred that the acid generator (B) includes a compound represented by the following formula (2). Due to including the compound having the following structure, which compound having superior dispersibility in the directed self-assembling film formed from the composition for pattern formation, the acid generator (B) enables the rectangularity of the cross-sectional shape of the pattern to be further improved.

R²—R³—SO₃⁻X⁺ (2)

In the above formula (2), R² represents a monovalent group that includes an alicyclic structure having at least 6 ring atoms, or a monovalent group that includes an aliphatic heterocyclic structure having at least 6 atoms; R³ represents a fluorinated alkanediyl group having 1 to 10 carbon atoms; and X⁺ represents a monovalent radioactive ray-degradable onium cation.

Examples of the monovalent group that includes an alicyclic structure having at least 6 ring atoms which may be represented by R² include

monocyclic cycloalkyl groups such as a cyclohexyl group, a cycloheptyl group, a cyclooctyl group, a cyclononyl group, a cyclodecyl group and a cyclododecyl group;

monocyclic cycloalkenyl groups such as a cyclohexenyl group, a cycloheptenyl group, a cyclooctenyl group and a cyclodecenyl group;

polycyclic cycloalkyl groups such as a norbornyl group, an adamantyl group, a tricyclodecyl group and a tetracyclododecyl group;

polycyclic cycloalkenyl groups such as a norbornenyl group and a tricyclodecenyl group; and the like.

Examples of the monovalent group that includes an aliphatic heterocyclic structure having at least 6 atoms which may be represented by R² include:

groups that include a lactone structure such as a norbornanelactone-yl group;

groups that include a sultone structure such as a norbornanesultone-yl group;

oxygen atom-containing heterocyclic groups such as an oxacycloheptyl group and an oxanorbornyl group;

nitrogen atom-containing heterocyclic groups such as an azacyclohexyl group, an azacycloheptyl group and a diazabicyclooctan-yl group;

sulfur atom-containing heterocyclic groups such as a thiacycloheptyl group and a thianorbornyl group; and the like.

The number of the ring atoms of the group represented by R² is, in light of attaining a more adequate diffusion length of the acid, preferably no less than 8, more preferably 9 to 15, and still more preferably 10 to 13.

Of these, R² represents preferably a monovalent group that includes an alicyclic structure having at least 9 ring atoms and a monovalent group that includes an aliphatic heterocyclic structure having at least 6 atoms, and more preferably an adamantyl group, a hydroxyadamantyl group, a norbornanelactone-yl group, a 5-oxo-4-oxatricyclo[4.3.1.1^{3,8}]undecan-yl group, an adamantan-1-yloxycarbonyl group, a norbornanesulton-2-yloxycarbonyl group and a piperidin-1-ylsulfonyl group.

Examples of the fluorinated alkanediyl group having 1 to 10 carbon atoms represented by R³ described above include groups obtained by substituting one or more hydrogen atoms, which are included in an alkanediyl group having 1 to 10 carbon atoms such as a methanediyl group, an ethanediyl group and a propanediyl group, with a fluorine atom, and the like.

Of these, the fluorinated alkanediyl group having 1 to 10 carbon atoms represented by R³ is preferably a fluorinated alkanediyl group in which a fluorine atom bonds to the carbon atom adjacent to the SO₃⁻ group, more preferably a fluorinated alkanediyl group in which two fluorine atoms bond to the carbon atom adjacent to the SO₃⁻ group, and still more preferably a 1,1-difluoromethanediyl group, a 1,1-difluoroethanediyl group, a 1,1,3,3,3-pentafluoro-1,2-propanediyl group, a 1,1,2,2-tetrafluoroethanediyl group, a 1,1,2,2-tetrafluorobutanediyl group, a 1,1,2,2-tetrafluorohexanediyl group, a 1,1,2-trifluorobutanediyl group and a 1,1,2,2,3,3-hexafluoropropanediyl group.

The monovalent radioactive ray-degradable onium cation represented by X⁺ is a cation degraded by an irradiation with exposure light. At light-exposed sites, a sulfonic acid is generated from a sulfonate anion and a proton generated by the degradation of the radioactive ray-degradable onium cation. The monovalent radioactive ray-degradable onium cation represented by X⁺ is exemplified by radioactive ray-degradable onium cations that include an element such as S, I, O, N, P, Cl, Br, F, As, Se, Sn, Sb, Te or Bi. Examples of the cation that includes S (sulfur) as the element include sulfonium cations, tetrahydrothiophenium cations and the like, and examples of the cation that includes I (iodine) as the element include iodonium cations and the like. Of these, sulfonium cations represented by the following formula (X-1), tetrahydrothiophenium cations represented by the following formula (X-2), and iodonium cations represented by the following formula (X-3) are preferred.

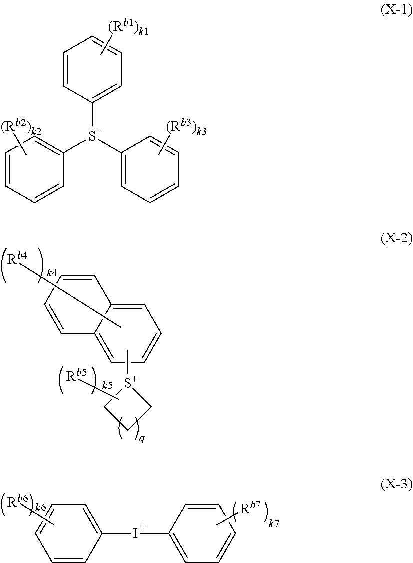

In the above formula (X-1), R^{b1}, and R^{b3} each independently represent a substituted or unsubstituted linear or branched alkyl group having 1 to 12 carbon atoms, a substituted or unsubstituted aromatic hydrocarbon group having 6 to 12 carbon atoms, —OSO₂—R^{P} or —SO₂—R^{Q}, or represent a ring structure constituted with two or more among these groups taken together; R^{P} and R^{Q} each independently represent a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms; k1, k2 and k3 are each independently an integer of 0 to 5, wherein each of R^{b1} to R^{b3}, and each of R^{P} and R^{Q} are present in a plurality of number, a plurality of R^{b1}s to R^{b3}s, and a plurality of R^{P}s and R^{Q}s are each the same or different with each other.

In the above formula (X-2), R^{b4} represents a substituted or unsubstituted linear or branched alkyl group having 1 to 8 carbon atoms, or a substituted or unsubstituted aromatic hydrocarbon group having 6 to 8 carbon atoms; k4 is an integer of 0 to 7, wherein in a case in which R^{b4} is present in a plurality of number, a plurality of R^{b4}s may be identical or different, and a plurality of R^{b4}s may taken together represent a ring structure; R^{b5} represents a substituted or unsubstituted linear or branched alkyl group having 1 to 7 carbon atoms, or a substituted or unsubstituted aromatic hydrocarbon group having 6 or 7 carbon atoms; k5 is an integer of 0 to 6, wherein in a case in which R^{b5} is present in a plurality of number, a plurality of R^{b5}s may be identical or different, and a plurality of R^{b5}s may taken together represent a ring structure; and q is an integer of 0 to 3.

In the above formula (X-3), R^{b6} and R^{b7} each independently represent a substituted or unsubstituted linear or branched alkyl group having 1 to 12 carbon atoms, a substituted or unsubstituted aromatic hydrocarbon group having 6 to 12 carbon atoms, —OSO₂—R^{R} or —SO₂—R^{S}, or represent a ring structure constituted with two or more among these groups taken together; R^{R} and R^{S} each independently represent a substituted or unsubstituted linear or branched alkyl group having 1 to 12 carbon atoms, a substituted or unsubstituted alicyclic hydrocarbon group having 5 to 25 carbon atoms or a substituted or unsubstituted aromatic hydrocarbon group having 6 to 12 carbon atoms; k6 and k7 are each independently an integer of 0 to 5; wherein in a case in which each of R^{b6}, R^{b7}, R^{R} and R^{S} are present in a plurality of number, a plurality of R^{b6}s, R^{b7}s, R^{R}s and R^{S}s are each the same or different with each other.

Examples of the unsubstituted linear alkyl group which may be represented by R^{b1} to R^{b7} include a methyl group, an ethyl group, a n-propyl group, a n-butyl group, and the like.

Examples of the unsubstituted branched alkyl group which may be represented by R^{b1} to R^{b7} include an i-propyl group, an i-butyl group, a sec-butyl group, a t-butyl group, and the like.

Examples of the unsubstituted aromatic hydrocarbon group which may be represented by R^{b1} to R^{b3}, R^{b6} and R^{b7} include aryl groups such as a phenyl group, a tolyl group, a xylyl group, a mesityl group and a naphthyl group; aralkyl groups such as a benzyl group and a phenethyl group, and the like.

Examples of the unsubstituted aromatic hydrocarbon group represented by R^{b4} and R^{b5} include a phenyl group, a tolyl group, a benzyl group, and the like.

Examples of the substituent which may substitute for the hydrogen atom included in the alkyl group and the aromatic hydrocarbon group include halogen atoms such as a fluorine atom, a chlorine atom, a bromine atom and an iodine atom, a hydroxy group, a carboxy group, a cyano group, a nitro group, an alkoxy group, an alkoxycarbonyl group, an alkoxycarbonyloxy group, an acyl group, an acyloxy group, and the like. Of these, halogen atoms are preferred, and a fluorine atom is more preferred.

R^{b1} to R^{b7} represent preferably an unsubstituted linear or branched alkyl group, a fluorinated alkyl group, an unsubstituted monovalent aromatic hydrocarbon group, —OSO₂—R″ or —SO₂—R″, more preferably a fluorinated alkyl group or an unsubstituted monovalent aromatic hydrocarbon group, and still more preferably a fluorinated alkyl group, wherein R″ represents an unsubstituted monovalent alicyclic hydrocarbon group, or an unsubstituted monovalent aromatic hydrocarbon group.

In the above formula (X-1), k1, k2 and k3 are an integer of preferably 0 to 2, more preferably 0 or 1, and still more preferably 0.

In the above formula (X-2): k4 is an integer of preferably 0 to 2, more preferably 0 or 1, and still more preferably 1; k5 is an integer of preferably 0 to 2, more preferably 0 or 1, and still more preferably 0.

In the above formula (X-3), k6 and k7 are an integer of preferably 0 to 2, more preferably 0 or 1, and still more preferably 0.

X⁺ is preferably a cation represented by the above formulae (X-1) and (X-3), and more preferably a triphenylsulfonium cation and a diphenyliodonium cation.

The acid generating agent represented by the above formula (2) is exemplified by compounds represented by the following formulae (2-1) to (2-14) (hereinafter, may be also referred to as “compounds (2-1) to (2-14)”), and the like.

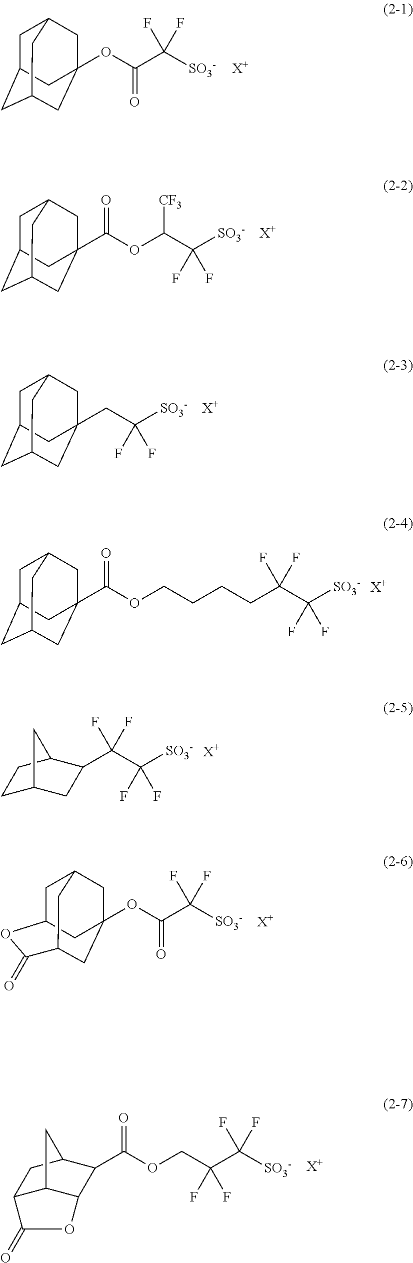

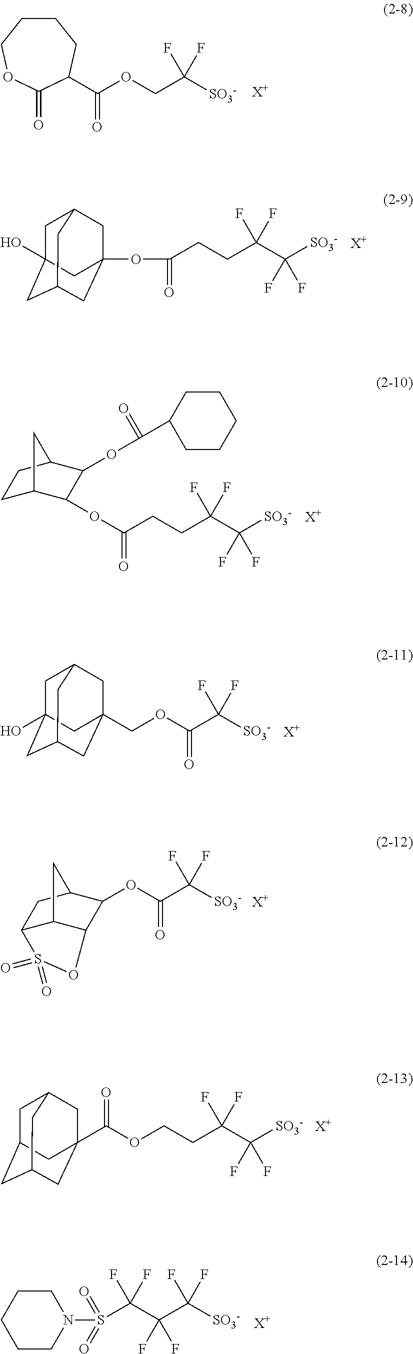

Among these, the acid generating agent (B) is preferably an onium salt compound, more preferably a sulfonium salt, an iodonium salt and a tetrahydrothiophenium salt, and still more preferably the compound (2-1), the compound (2-5), the compound (2-13), the compound (2-14) and di(t-butylphenyl)iodonium nonafluorobutanesulfonate.

In the case where the acid generator (B) is the acid generating agent (B), the content of the acid generator (B) with respect to 100 parts by mass of the polymer (A) is, in light of making the pattern configuration of a pattern formed from the composition for pattern formation favorable, preferably no less than 0.1 parts by mass and no greater than 30 parts by mass, more preferably no less than 0.5 parts by mass and no greater than 20 parts by mass, still more preferably no less than 1 part by mass and no greater than 15 parts by mass, and particularly preferably no less than 3 parts by mass and no greater than 15 parts by mass. When the content of the acid generating agent (B) falls within the above range, the rectangularity of the pattern formed from the composition for pattern formation may be improved. One, or two or more types of the acid generator (B) may be used.

### (C) Solvent

The composition for pattern formation typically contains (C) a solvent (C). Examples of the solvent (C) include similar solvents to those exemplified in connection with the synthesis method of the block copolymer (A1). Of these, propylene glycol monomethyl ether acetate, and cyclohexanone are preferred. It is to be noted that these solvents may be used alone, or two or more types thereof may be used in combination.

### Surfactant

The composition for pattern formation may further contain a surfactant. When the composition for pattern formation contains the surfactant, coating properties to the substrate and the like can be improved.

### Preparation Method of Composition for Pattern Formation

The composition for pattern formation may be prepared, for example, by mixing the polymer (A), the surfactant and the like at a certain ratio in the solvent (C). Alternatively, the composition for pattern formation may be prepared in a state which has been dissolved or dispersed in an appropriate solvent, and may be put the solution into use.

### Pattern-Forming Method

The pattern-forming method according to the embodiment of the present invention includes the step of: providing a directed self-assembling film having a phase separation structure on a substrate (hereinafter, may be also referred to as “directed self-assembling film-providing step”).

Moreover, it is preferred that the pattern-forming method further includes the step of forming a prepattern (hereinafter, may be also referred to as “prepattern-forming step”), and the directed self-assembling film-providing step is carried out after the prepattern-forming step.

Furthermore, the pattern-forming method may include the step of removing a part of a plurality of phases of the directed self-assembling film (hereinafter, may be also referred to as “partially removing step”).

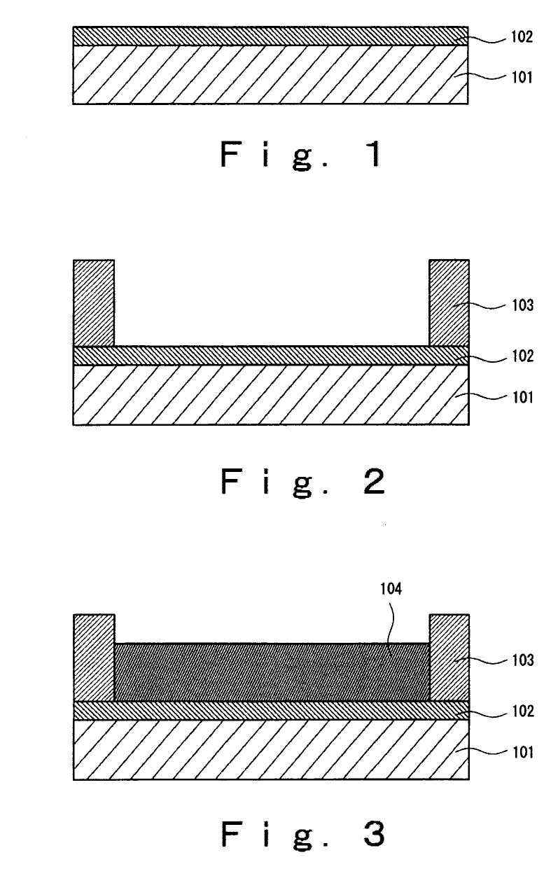

Additionally, it is preferred that the pattern-forming method further includes: the step of providing an underlayer film on the substrate (hereinafter, may be also referred to as “underlayer film-providing step”); the step of removing the prepattern after the directed self-assembling film-providing step (hereinafter, may be also referred to as “prepattern-removing step”); the step of etching the substrate after the partially removing step, using the pattern formed above as a mask (hereinafter, may be also referred to as “pattern-forming step”). Hereinafter, each step will be described in detail. It is to be noted that each step will be explained with reference to FIGS. 1 to 5 by way of an example in which the polymer (A) is the block copolymer (A1).

### Underlayer Film-Providing Step

In this step, an underlayer film is provided on a substrate using a composition for forming an underlayer film. Thus, as shown in FIG. 1, a substrate having an underlayer film can be obtained which includes an underlayer film 102 provided on a substrate 101, and the directed self-assembling film is provided on the underlayer film 102. The phase separation structure (microdomain structure) included in the directed self-assembling film is altered by not only an interaction between each of the blocks, but also an interaction with the underlayer film 102; therefore, the structure may be easily controlled by virtue of having the underlayer film 102, whereby a desired pattern can be obtained. Furthermore, when the directed self-assembling film is thin, a transfer process thereof can be improved owing to having the underlayer film 102.

As the substrate 101, for example, a conventionally well-known substrate, e.g., a silicon wafer, a wafer coated with aluminum, or the like may be used.

Furthermore, as the composition for forming an underlayer film, a conventionally well-known organic material for forming an underlayer film may be used.

Although the procedure for providing the underlayer film 102 is not particularly limited, the underlayer film 102 may be formed by, for example, curing a coating film through exposing and/or heating, which had been provided by an application according to a well-known method such as a spin coating method on the substrate 101. Examples of the radioactive ray which may be employed for the exposure include visible light rays, ultraviolet rays, far ultraviolet rays, X-rays, electron beams, γ-rays, molecular beams, ion beams, and the like. Moreover, the temperature employed during heating the coating film is not particularly limited, and is preferably 90° C. to 550° C., more preferably 90° C. to 450° C., and still more preferably 90° C. to 300° C. Also, the film thickness of the underlayer film 102 is not particularly limited, and is preferably 50 nm to 20,000 nm, and more preferably 70 nm to 1,000 nm. In addition, the underlayer film 102 preferably includes an SOC (Spin on carbon) film.

### Prepattern-Forming Step

According to this step, a prepattern 103 is formed by using a composition for prepattern formation on the underlayer film 102 as shown in FIG. 2. The prepattern 103 enables a desired fine pattern to be formed through controlling a pattern configuration obtained by phase separation in the composition for pattern formation. More specifically, among the blocks included in the block copolymer (A1) contained in the composition for pattern formation, a block having a higher affinity to a lateral face of the prepattern forms phases along the prepattern, whereas a block having a lower affinity forms phases at positions away from the prepattern. Accordingly, a desired pattern can be formed. In addition, according to the material, size, shape, etc. of the prepattern, the structure of the pattern formed through phase separation of the composition for pattern formation can be more minutely controlled. It is to be noted that the prepattern may be appropriately selected depending on the pattern intended to be finally formed, and, for example, a line-and-space pattern, a hole pattern, and the like may be employed.

As the method for forming the prepattern 103, those similar to well-known resist pattern-forming methods, and the like may be employed. In addition, a conventional composition for resist film formation may be used as the composition for prepattern formation.

In a specific method for formation of the prepattern 103, for example, a commercially available chemical amplification resist composition is coated on the underlayer film 102 to provide a resist film. Next, an exposure is carried out by irradiating a desired region of the resist film with a radioactive ray through a mask having a specific pattern. Examples of the radioactive ray include ultraviolet rays, far ultraviolet rays, X-rays, charged particle rays, and the like. Of these, far ultraviolet rays typified by ArF excimer laser beams and KrF excimer lasers are preferred, and ArF excimer laser beams are more preferred. Also, the exposure may employ a liquid immersion medium. Subsequently, post exposure baking (PEB) is carried out, followed by development using a developer solution such as an alkaline developer solution and an organic solvent, whereby a desired prepattern 103 can be formed.

It is to be noted that the surface of the prepattern 103 may be subjected to a hydrophobilization treatment or a hydrophilization treatment. In specific treatment methods, a hydrogenation treatment including exposing to hydrogen plasma for a certain time period, and the like may be adopted. An increase of the hydrophobicity or hydrophilicity of the surface of the prepattern 103 enables the directed self-assembly of the composition for pattern formation to be accelerated.

### Directed Self-Assembling Film-Providing Step

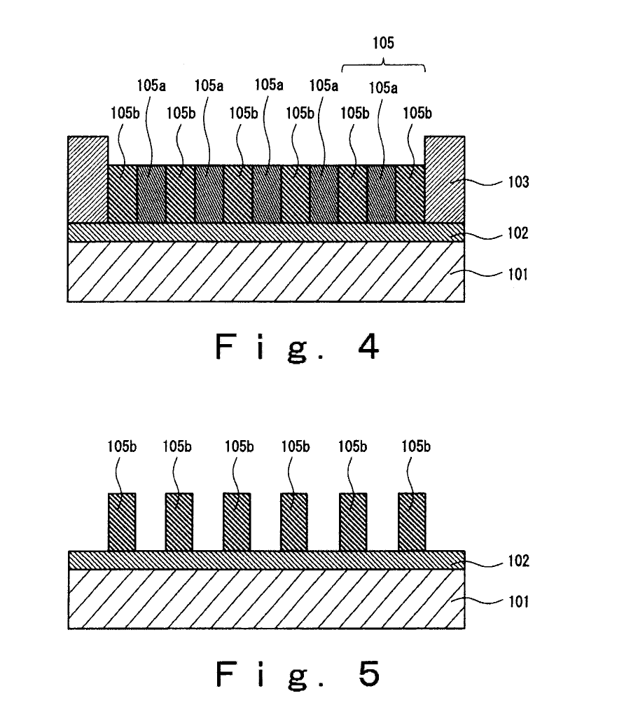

In this step, a directed self-assembling film having a phase separation structure is provided directly or indirectly on the substrate using the composition for pattern formation. In a case where the underlayer film and the prepattern are not used, the composition for pattern formation is directly coated on the substrate to give a coating film, whereby the directed self-assembling film having a phase separation structure is provided. Alternatively, in a case where the underlayer film and the prepattern are used, as shown in FIGS. 3 and 4, the composition for pattern formation is coated on a region surrounded by the prepattern 103 on the underlayer film 102 to give the coating film 104, and a directed self-assembling film 105 having a phase separation structure that includes an interface substantially perpendicular to the substrate 101 is formed on the underlayer film 102 provided on the substrate 101.

More specifically, in a case where the polymer (A) is the block copolymer (A1) including two or more types of blocks incompatible with one another, coating the composition for pattern formation on the substrate, followed by annealing and the like allows blocks having identical properties to be assembled with one another to spontaneously form an ordered pattern, and thus enables directed self-assembly, as generally referred to, to be accelerated. Accordingly, a directed self-assembling film having a phase separation structure such as a sea-island structure, a cylinder structure, a co-interconnected or a lamellar structure can be formed. The phase separation structure preferably has phase boundaries substantially perpendicular to the substrate 101. In this step, the use of the composition for pattern formation according to the embodiment of the present invention enables occurrence of phase separation to be facilitated, and therefore a finer phase separation structure (microdomain structure) can be formed.

When the prepattern is included, the phase separation structure is preferably formed along the prepattern, and the boundaries formed by the phase separation are more preferably substantially parallel to a lateral face of the prepattern. For example, in a case where the block copolymer (A1) is constituted with a styrene block and a poly(meth)acrylate block, and the prepattern 103 has a higher affinity to the styrene block, a phase (105b) of the styrene block is linearly formed along the prepattern 103, and adjacent to the phase (105b), a phase (105a) of the poly(meth)acrylate block and the phase (105b) of the styrene block are alternately arranged in this order to form a lamellar phase separation structure, or the like. It is to be noted that the phase separation structure formed in this step is configured with a plurality of phases, and the boundaries formed by these phases are, in general, substantially perpendicular to the substrate; however, the boundaries per se may not necessarily be clear. In addition, the resultant phase separation structure can be more strictly controlled by way of a ratio of the length of each block chain in molecules of the block copolymer (A1), the length of the molecule of the block copolymer (A1), the prepattern, the underlayer film and the like, and thus, a directed fine pattern can be obtained.

Although the procedure for providing the coating film 104 by coating the composition for pattern formation on a substrate is not particularly limited, for example, a procedure in which the composition for pattern formation employed is coated by spin coating etc., and the like may be involved. Accordingly, a space between facing walls of the prepattern 103 on the underlayer film 102 is filled with the composition for pattern formation.

The annealing process may include, for example, heating at a temperature of 80° C. to 400° C. in an oven, on a hot plate, etc., and the like. The annealing time period is typically 1 min to 120 min, and preferably 5 min to 90 min. The film thickness of the resulting directed self-assembling film 105 is preferably 0.1 nm to 500 nm, and more preferably 0.5 nm to 100 nm.

In a case where the acid generator (B) is the thermal acid generator (B2), an acid is generated by the annealing, and this acid allows the crosslinking reaction of the crosslinkable group in the block copolymer (A1) to be further accelerated, whereby the etching resistance of a part of the plurality of phases in the block copolymer (A1) is further improved. Consequently, the rectangularity of the cross-sectional shape can be further improved.

In a case where the acid generator (B) is the photoacid generator (B1), it is preferred that an exposure is carried out prior to the annealing. When the exposure is thus carried out prior to the annealing, the rectangularity of the cross-sectional shape can be further improved, similarly to the case of the thermal acid generator (B2) described above. The light for use in the exposure is not particularly limited as long as the light can generate an acid from the photoacid generator (B1), and examples of the light include: electromagnetic waves such as visible light rays, ultraviolet rays, far ultraviolet rays, EUV, X-rays and γ-rays; electron beams, charged particle rays such as α-rays; and the like. Among these, far ultraviolet rays, EUV and electron beams are preferred, and ArF excimer laser beams (wavelength: 193 nm), KrF excimer laser beams (wavelength: 248 nm) and electron beams are more preferred.

### Partially Removing Step

In this step, any one type of the phases in the phase separation structure included in the directed self-assembling film 105 is removed. In this case, as shown in FIGS. 4 and 5, phases 105a formed from the block “a” are removed. Using the difference in the etching rate between the phases formed from the block “a” and the phases formed from the block “b” obtained through the phase separation by the directed self-assembly, the phases 105a formed from the block “a” can be removed by an etching treatment. A state after removing the phases 105a formed from the block “a”, as well as the prepattern 103 removed in the prepattern-removing step described later is shown in FIG. 5.

As the procedure for removing the phases 105a formed from the block “a”, well-known procedures e.g., reactive ion etching (RIE) such as chemical dry etching and chemical wet etching; physical etching such as sputter etching and ion beam etching; and the like may be exemplified. Of these, reactive ion etching (RIE) is preferred, and chemical dry etching carried out by using a CF₄ gas, an O₂ gas or the like, and chemical wet etching (wet development) carried out by using an etching solution, i.e., an organic solvent, or a liquid such as hydrofluoric acid are more preferred. Examples of the organic solvent include: alkanes such as n-pentane, n-hexane and n-heptane; cycloalkanes such as cyclohexane, cycloheptane and cyclooctane; saturated carboxylic acid esters such as ethyl acetate, n-butyl acetate, i-butyl acetate and methyl propionate; ketones such as acetone, 2-butanone, 4-methyl-2-pentanone and 2-heptanone; alcohols such as methanol, ethanol, 1-propanol, 2-propanol and 4-methyl-2-pentanol; and the like. It is to be noted that these solvents may be used either alone, or two or more types thereof may be used in combination.

It is to be noted that prior to the etching treatment, irradiation with a radioactive ray may be conducted as needed. As the radioactive ray, in a case where the phases to be removed by etching are the phases formed from the poly(meth)acrylate block, a radioactive ray of 254 nm may be used. The irradiation with the radioactive ray results in decomposition of the phases formed from the poly(meth)acrylate block, whereby the etching can be facilitated.

### Prepattern-Removing Step

In this step, the prepattern 103 is removed, as shown in FIGS. 4 and 5. Removal of the prepattern 103 enables a finer and complicated pattern to be formed. It is to be noted that with respect to the procedure for removing the prepattern 103, a procedure similar to that in the removal of the phases 105a formed from the block “a” described above may be employed. Also, this step may be carried out concomitantly with the partially removing step, or may be carried out before or after the partially removing step.

### Pattern-Forming Step

In this step, using as a mask, a pattern constituted with residual phases 105b formed from the block “b” after the partially removing step, the underlayer film and the substrate are etched to permit patterning. After completion of the patterning onto the substrate, the phases used as a mask are removed from the substrate by a dissolving treatment or the like, whereby a patterned substrate (pattern) can be finally obtained.

As the procedure for the etching, a procedure similar to that in the partially removing step may be employed, and the etching gas and the etching solution may be appropriately selected in accordance with the materials of the underlayer film and the substrate. For example, in a case where the substrate is a silicon material, a gas mixture of chlorofluorocarbon-containing gas and SF₄, or the like may be used. Alternatively, in a case where the substrate is a metal film, a gas mixture of BCl₃ and Cl₂, or the like may be used. Note that the pattern obtained according to the pattern-forming method is suitably used for semiconductor elements and the like, and further the semiconductor elements are widely used for LED, solar cells, and the like.

In the present embodiment, a case in which the phases formed from the block “a” are removed, whereas the phases formed from the block “b” remain in the partially removing step is explained by way of example; however, it is also acceptable that the phases formed from the block “b” are removed, whereas the phases formed from the block “a” remain.

In addition, also in the case where the polymer (A) is the polymer (A2), a pattern can be similarly formed according to the foregoing process.

### EXAMPLES

Hereinafter, the present invention is explained in detail by way of Examples, but the present invention is not in any way limited to these Examples. Measuring methods of physical properties are shown below.

### Weight Average Molecular Weight (Mw) and Number Average Molecular Weight (Mn)

The Mw and the Mn of the polymer were determined by gel permeation chromatography (GPC) using GPC columns (“G2000 HXL”×2, “G3000 HXL”×1, “G4000 HXL”×1, manufactured by Tosoh Corporation) under the following condition:

eluent: tetrahydrofuran (Wako Pure Chemical Industries, Ltd.);

flow rate: 1.0 mL/min;

sample concentration: 1.0% by mass;

amount of sample injected: 100 μL;

detector: differential refractometer; and

standard substance: mono-dispersed polystyrene.

### ¹³C-NMR Analysis

¹³C-NMR analysis for determining the proportion of each structural unit included in the polymer was carried out using a nuclear magnetic resonance apparatus (“JNM-EX400”, available from JEOL, Ltd.).

### Synthesis of Polymer (A)

According to the following method, each polymer (A) was synthesized. Monomers used in the synthesis of the polymer (A) are shown below.

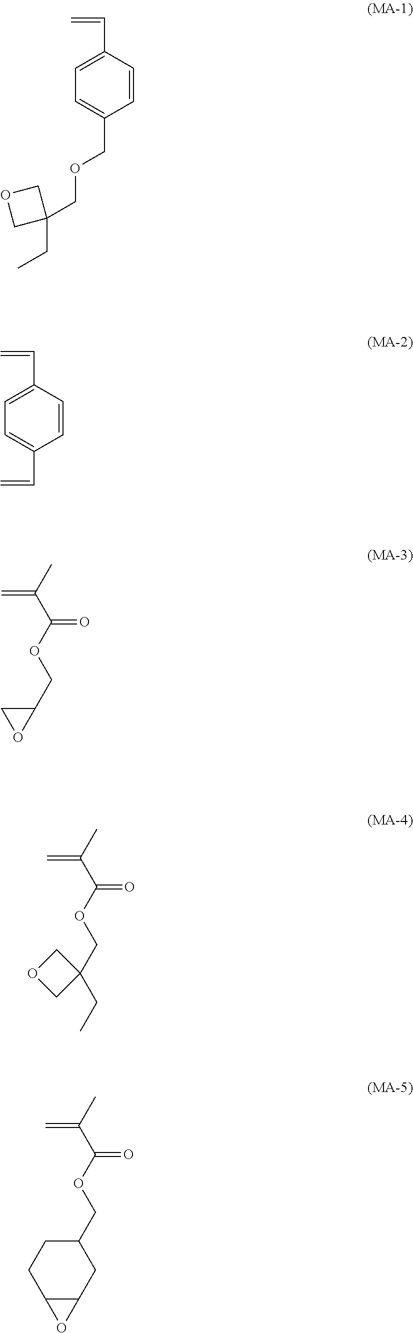

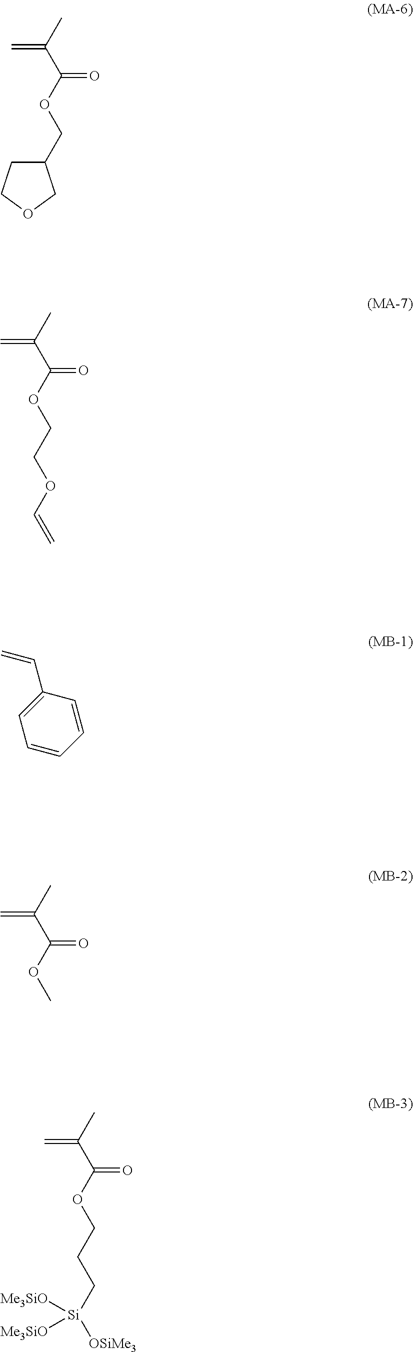

### Synthesis of Block Copolymer (A1)

### Synthesis Example 1

### Synthesis of Block Copolymer (A1-1)

Synthesis Step of Polystyrene Block

After a 500 mL flask as a reaction vessel was dried under reduced pressure, 200 g of tetrahydrofuran, which had been subjected to a dehydrating treatment by distillation, was charged into the flask under a nitrogen atmosphere, and cooled to −78° C. Thereafter, 1.09 mL (0.98 mmol) of a 1 N sec-butyllithium (sec-BuLi) solution in cyclohexane was charged, and 8.57 g (82.4 mmol) of the compound (MB-1) and 4.78 g (20.6 mmol) of the compound (MA-1), both of which had been subjected to a dehydrating treatment by distillation, were added dropwise over 30 min. During this dropwise addition, the internal temperature of the reaction solution was carefully adjusted so as not to be −60° C. or higher. After the completion of the dropwise addition, the mixture was aged for 30 min. Then, 3.91 mL (1.96 mmol) of lithium chloride and 0.42 mL (2.94 mmol) of diphenylethylene were added thereto, and the mixture was sufficiently stirred to synthesize a polystyrene block.

Synthesis Step of Poly(Meth)Acrylate Block

To the solution of the polystyrene block was added 10.31 g (103 mmol) of the compound (MB-2) dropwise over 30 min, which had been subjected to a dehydrating treatment by distillation, and the mixture was aged for 120 min. To this solution was added 0.032 g (1.00 mmol) of methanol to allow the polymerization end to be terminated, and the product was precipitated in methanol and the solvent was distilled off to give a white solid.

Purification Step

The white solid obtained after the distillation of the solvent was diluted with methyl isobutyl ketone to prepare a 10% by mass solution. To this solution was added 500 g of a 1% by mass aqueous oxalic acid solution with stirring, and after the mixture was left to stand, the underlayer, i.e., an aqueous layer, was discarded. This operation was repeated three times to remove metal lithium. Then, 500 g of ultra pure water was charged, the mixture was stirred, and then the underlayer, i.e., an aqueous layer, was discarded. This operation was repeated three times to remove oxalic acid. Thereafter, the solution was concentrated, and then the mixture was added dropwise to 2,000 g of methanol to permit deposition of a polymer. The resin obtained after vacuum filtration was washed twice with methanol, and then dried at 60° C. under reduced pressure to obtain 23.2 g of a white block copolymer (A1-1).

The block copolymer (A1-1) had an Mw of 41,000, an Mn of 37,000, and an Mw/Mn of 1.10. It is to be noted that the block copolymer (A1-1) was a triblock copolymer including polystyrene blocks and a poly((meth)acrylic acid ester) block, with one of two types of the styrene blocks having a vinyl group in a side chain thereof.

### Synthesis Examples 2 to 8

Block copolymers (A1-3) to (A1-7) and (CA1-1) were synthesized in a similar manner to Synthesis Example 1 except that the type and the amount of each monomer employed were as shown in Table 1 below. Furthermore, a block copolymer (A1-2) was synthesized in a similar manner to Synthesis Example 1 except that the type and the amount of each monomer employed were as shown in Table 1 below, and that potassium tert-butoxide was used in place of sec-butyllithium in the aforementioned Synthesis Step of Polystyrene Block. It is to be noted that the compounds (MA-1), (MA-2), (MB-1) and (MB-4) were used in the aforementioned Synthesis Step of Polystyrene Block, and the compounds (MA-3) to (MA-7), (MB-2) and (MB-3) were used in the aforementioned Synthesis Step of Poly(meth)acrylate Block. The proportion of each structural unit contained in these polymers, the yield (%), the Mw and the Mw/Mn are shown in Table 2.

TABLE 1

| | | Monomer that gives | | | | | | | | |
|---|---|---|---|---|---|---|---|---|---|---|
| | | structural unit (I) | | | Other monomer | | | | | |
| | | | using | | | using | | | using | |
| | | | amount | | | amount | | | amount | |
| | (A) Component | type | g | mmol | type | g | mmol | type | g | mmol |
| Synthesis Example 1 | A1-1 | MA-1 | 4.78 | 20.6 | MB-1 | 8.57 | 82.4 | MB-2 | 10.31 | 103 |
| Synthesis Example 2 | A1-2 | MA-2 | 2.68 | 20.6 | MB-1 | 8.57 | 82.4 | MB-2 | 10.31 | 103 |
| Synthesis Example 3 | A1-3 | MA-3 | 8.71 | 20.6 | MB-1 | 10.7 | 103 | MB-3 | 34.84 | 82.4 |
| Synthesis Example 4 | A1-4 | MA-4 | 3.79 | 20.6 | MB-1 | 10.7 | 103 | MB-3 | 34.84 | 82.4 |
| Synthesis Example 5 | A1-5 | MA-5 | 4.04 | 20.6 | MB-1 | 10.7 | 103 | MB-3 | 34.84 | 82.4 |
| Synthesis Example 6 | A1-6 | MA-6 | 3.50 | 20.6 | MB-1 | 10.7 | 103 | MB-3 | 34.84 | 82.4 |
| Synthesis Example 7 | A1-7 | MA-7 | 3.22 | 20.6 | MB-1 | 10.7 | 103 | MB-3 | 34.84 | 82.4 |
| Synthesis Example 8 | CA1-1 | — | — | — | MB-1 | 10.7 | 103 | MB-2 | 10.31 | 103 |

TABLE 2

| | (A) | Yield | | | |
|---|---|---|---|---|---|
| | Component | (%) | Mw | Mn | Mw/Mn |
| Synthesis Example 1 | A1-1 | 98 | 41,000 | 37,200 | 1.10 |
| Synthesis Example 2 | A1-2 | 98 | 41,300 | 38,500 | 1.07 |
| Synthesis Example 3 | A1-3 | 98 | 41,400 | 39,500 | 1.05 |
| Synthesis Example 4 | A1-4 | 98 | 40,300 | 38,200 | 1.05 |
| Synthesis Example 5 | A1-5 | 98 | 39,000 | 36,500 | 1.07 |
| Synthesis Example 6 | A1-6 | 98 | 39,000 | 36,500 | 1.07 |
| Synthesis Example 7 | A1-7 | 98 | 39,000 | 36,500 | 1.07 |
| Synthesis Example 8 | CA1-1 | 99 | 39,000 | 36,500 | 1.07 |

### Synthesis Example 9

### Synthesis of Polymer (P-1)

After a 500 mL flask as a reaction vessel was dried under reduced pressure, 200 g of tetrahydrofuran, which had been subjected to a dehydrating treatment by distillation, was charged into the flask under a nitrogen atmosphere, and cooled to −78° C. Thereafter, 1.00 mL (1.00 mmol) of a 1 N potassium tert-butoxide (tert-BuOK) solution in tetrahydrofuran, and 0.10 mL (0.10 mmol) of a 1 N sec-butyllithium solution in cyclohexane were charged, and 0.00118 g (0.01 mmol) of α-methylstyrene and 26.7 g (0.205 mol) of the compound (MA-2) which had been subjected to a dehydrating treatment by distillation were added dropwise thereto over 30 min. During this dropwise addition, the internal temperature of the reaction solution was carefully adjusted so as not to be −60° C. or higher. After the completion of the dropwise addition, the mixture was aged for 30 min. Then, 0.032 g (1.00 mmol) of methanol was added to allow the polymerization end to be terminated, and the product was precipitated in methanol and the solvent was distilled off to give a white solid. Thereafter, the purification step was carried out to give 26.4 g of a a styrene polymer (P-1). The styrene polymer (P-1) had an Mw of 41,300, an Mn of 38,500, and an Mw/Mn of 1.07.

### Synthesis Example 10

### Synthesis of Polymer (P-2)

After a 500 mL flask as a reaction vessel was dried under reduced pressure, 200 g of tetrahydrofuran, which had been subjected to a dehydrating treatment by distillation, was charged into the flask under a nitrogen atmosphere, and cooled to −78° C. Thereafter, 1.09 mL (0.98 mmol) of a 1 N sec-butyllithium (sec-BuLi) solution in cyclohexane was charged, and 21.4 g (206 mmol) of the compound (MB-1) which had been subjected to a dehydrating treatment by distillation was added dropwise over 30 min. During this dropwise addition, the internal temperature of the reaction solution was carefully adjusted so as not to be −60° C. or higher. After the completion of the dropwise addition, the mixture was aged for 30 min. Then, 0.032 g (1.00 mmol) of methanol was added to allow the polymerization end to be terminated, and the product was precipitated in methanol and the solvent was distilled off to give a white solid. Thereafter, the purification step was carried out to give 21.2 g of a styrene polymer (P-2). The styrene polymer (P-2) had an Mw of 39,000, an Mn of 36,500, and an Mw/Mn of 1.07.

### Synthesis Example 11

### Synthesis of Polymer (P-3)

After a 500 mL flask as a reaction vessel was dried under reduced pressure, 200 g of tetrahydrofuran, which had been subjected to a dehydrating treatment by distillation, was charged into the flask under a nitrogen atmosphere, and cooled to −78° C. Thereafter, 1.09 mL (0.98 mmol) of a 1 N sec-butyllithium (sec-BuLi) solution in cyclohexane was charged, and thereto were added 3.91 mL (1.96 mmol) of a 0.5 mol/L lithium chloride solution and 0.42 mL (2.94 mmol) of diphenylethylene which had been subjected to a dehydrating treatment by distillation and the mixture was sufficiently stirred. Thereto was added 20.62 g (206 mmol) of the compound (MB-2), which had been subjected to a dehydrating treatment by distillation, dropwise over 30 min, and the mixture was aged for 120 min. A small amount of dehydrated methanol was added to this solution to allow the polymerization end to be terminated, and the product was precipitated in methanol. The solvent was distilled off to give a white solid. Subsequently, the purification step was carried out to give 20.4 g of an acrylic polymer (P-3). The acrylic polymer (P-3) had an Mw of 39,000, an Mn of 36,500, and an Mw/Mn of 1.07. The monomers used in the synthesis of the polymers (P-1) to (P-3), the Mw and the like are shown in Table 3.

TABLE 3

| | | Monomer | | | | | | | |
|---|---|---|---|---|---|---|---|---|---|
| | | | using | | | | | | |
| | | | amount | | proportion of monomer | | | | |
| | Polymer | type | g | mmol | (% by mole) | Yield (%) | Mw | Mn | Mw/Mn |
| Synthesis Example 9 | P-1 | MA-2 | 26.7 | 205 | 100 | 98 | 41,300 | 38,500 | 1.07 |
| Synthesis Example 10 | P-2 | MB-1 | 21.4 | 206 | 100 | 99 | 39,000 | 36,500 | 1.07 |
| Synthesis Example 11 | P-3 | MB-2 | 20.62 | 206 | 100 | 99 | 39,000 | 36,500 | 1.07 |

### Preparation of Composition for Pattern Formation

Each component used in preparing each composition for pattern formation is shown below.

### (B) Acid Generating Agent

B-1: a compound represented by the following formula (B-1)

B-2: a compound represented by the following formula (B-2)

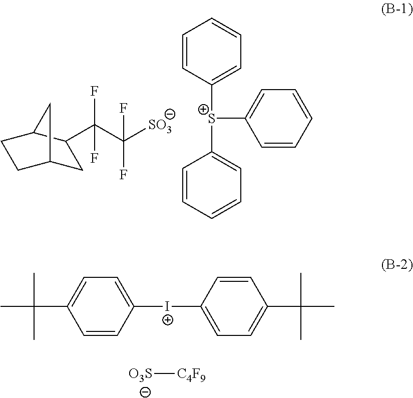

### (C) Solvent

C-1: propylene glycol monomethyl ether acetate (PGMEA)

C-2: cyclohexanone (CHN)

C-3: butyl acetate

### Examples 1 to 15, and Comparative Example 1

A composition for pattern formation (S1-1) was prepared by: mixing 10 parts by mass of (A1-1) as the block copolymer (A1), 5 parts by mass of (B-1) as the acid generating agent (B) and 1,500 parts by mass of (C-1) as the solvent (C); and then filtration through a membrane filter having a pore size of 200 nm. In a similar manner, compositions for pattern formation (S1-2) to (S1-15) and (CS1-1) were prepared using the block copolymer (A1) shown in Table 4.

### Examples 16 and 17, and Comparative Example 2

A composition for pattern formation (S2-1) was prepared by: mixing 5 parts by mass of (P-1) as the polymer (A2), 5 parts by mass of the polymer (P-3), 5 parts by mass of (B-1) as the acid generating agent (B), and 1,500 parts by mass of (C-1) as the solvent (C); and then filtration through a membrane filter having a pore size of 200 nm. In a similar manner, compositions for pattern formation (S2-2) and (CS2-1) were prepared using the polymer shown in Table 4.

TABLE 4

| | | | | (B) Acid | | | |
|---|---|---|---|---|---|---|---|
| | | (A) Polymer or | | generating | | | |
| | | Other polymer | | agent | | (C) Solvent | |
| | Composition | | content | | content | | content |
| | for pattern | | (parts by | | (parts by | | (parts by |
| | formation | type | mass) | type | mass) | type | mass) |
| Example 1 | S1-1 | A1-1 | 10 | B-1 | 5 | C-1 | 1,500 |
| Example 2 | S1-2 | A1-2 | 10 | B-1 | 5 | C-1 | 1,500 |
| Example 3 | S1-3 | A1-3 | 10 | B-1 | 5 | C-1 | 1,500 |
| Example 4 | S1-4 | A1-4 | 10 | B-1 | 5 | C-1 | 1,500 |
| Example 5 | S1-5 | A1-5 | 10 | B-1 | 5 | C-1 | 1,500 |
| Example 6 | S1-6 | A1-6 | 10 | B-1 | 5 | C-1 | 1,500 |
| Example 7 | S1-7 | A1-7 | 10 | B-1 | 5 | C-1 | 1,500 |
| Example 8 | S1-8 | A1-1 | 10 | B-2 | 5 | C-1 | 1,500 |
| Example 9 | S1-9 | A1-2 | 10 | B-2 | 5 | C-1/C-2 | 1,090/410 |
| Example 10 | S1-10 | A1-3 | 10 | B-2 | 5 | C-1 | 1,500 |
| Example 11 | S1-11 | A1-4 | 10 | B-2 | 5 | C-1 | 1,500 |
| Example 12 | S1-12 | A1-2 | 10 | — | — | C-1/C-3 | 1,090/410 |
| Example 13 | S1-13 | A1-1 | 10 | — | — | C-1 | 1,500 |
| Example 14 | S1-14 | A1-3 | 10 | — | — | C-1 | 1,500 |
| Example 15 | S1-15 | A1-4 | 10 | — | — | C-1 | 1,500 |
| Example 16 | S2-1 | P-1/P-3 | 5/5 | B-1 | 5 | C-1 | 1,500 |
| Example 17 | S2-2 | P-1/P-3 | 5/5 | — | — | C-1 | 1,500 |
| Comparative | CS1-1 | CA1-1 | 5/5 | — | — | C-1 | 1,500 |
| Example 1 | | | | | | | |
| Comparative | CS2-1 | P-2/P-3 | 5/5 | — | — | C-1 | 1,500 |
| Example 2 | | | | | | | |

### Synthesis of Composition for Forming Underlayer Film

To a flask equipped with a condenser and a stirrer were charged 100 parts by mass of methyl ethyl ketone, and nitrogen substitution was carried out. After heating to 80° C., a mixture of 100 parts by mass of methyl ethyl ketone, 51 parts by mass (0.49 mol) of styrene, 49 parts by mass (0.49 mol) of methyl methacrylate and 5 parts by mass of mercaptoundecene was mixed with a mixture of 5 parts by mass of 2,2′-azobis(2-propionitrile) and methyl ethyl ketone. Purification by precipitation was carried out in 3 L of methanol, whereby residual monomers, the initiator and the like were removed to give a solid content. The solid content had an Mw of 7,201, an Mn of 5,114 and an Mw/Mn of 1.41. Next, 15 parts by mass of the solid content were dissolved in 9,985 parts by mass of propylene glycol monomethyl ether acetate, and the solution was filtered through a membrane filter having a pore size of 0.1 μm to obtain a composition for forming an underlayer film.

### Pattern-Forming Method

The composition for forming an underlayer film was coated on a 12-inch silicon wafer using a spin coater (“CLEAN TRACK ACT12”, available from Tokyo Electron Limited) to provide a coating film having a film thickness of 5 nm. This coating film was subjected to an exposure using an ArF Immersion Scanner (“NSR S610C”, available from NIKON Corporation). Thereafter, baking was carried out at 220° C. for 120 sec to form an underlayer film having a film thickness of 10 nm.

Next, each directed self-assembling composition for pattern formation was coated on the underlayer film so as to have a thickness of 30 nm, and an exposure was carried out using the ArF Immersion Scanner (“NSR S610C”, available from NIKON Corporation). Subsequently, heating at 250° C. for 10 min allowed phase separation to occur, whereby a microdomain structure was formed. Thereafter, dry etching with O₂ plasma using a plasma etching apparatus (“Telius SCCM”, available from Tokyo Electron Limited) was carried out to form a pattern with 30-nm pitch.

### Evaluations

The pattern formed as described above was observed using a line-width measurement SEM (“S-4800”, available from Hitachi, Ltd.). Evaluation methods are shown below.

With respect to the fingerprint defect, the evaluation was made as: “A” when clear phase separation was ascertained and a defect was not found; and “B” when a portion in which unclear phase separation was present and a defect was found.

With respect to the rectangularity, a cross-sectional shape of the pattern was similarly observed, and the evaluation was made as: “A” when the pattern was recognized to be rectangular; “B” when undissolved matter, etc., was marked and tailing was found; and “C” when pattern collapse occurred.

The results of the evaluations of the fingerprint defect and rectangularity are shown in Table 5.

TABLE 5

| | Fingerprint defect | Rectangularity |
|---|---|---|
| Example 1 | A | A |
| Example 2 | A | A |
| Example 3 | A | A |
| Example 4 | A | A |
| Example 5 | A | A |
| Example 6 | A | A |
| Example 7 | A | A |
| Example 8 | A | A |
| Example 9 | A | A |
| Example 10 | A | A |
| Example 11 | A | A |
| Example 12 | A | A |
| Example 13 | A | B |
| Example 14 | A | B |
| Example 15 | A | B |
| Example 16 | A | A |
| Example 17 | A | A |
| Comparative Example 1 | A | C |
| Comparative Example 2 | A | C |

As shown in Table 5, when the compositions for pattern formation of Examples were used, the fingerprint defect was not found, and defects of the phase separation structure were inhibited. In addition, the rectangularity of the cross-sectional shape of the pattern tended to be superior. On the other hand, when the compositions for pattern formation of Comparative Examples were used, the rectangularity of the cross-sectional shape of the pattern tended to be inferior.

According to the composition for pattern formation and the pattern-forming method of the embodiments of the present invention, a pattern being sufficiently fine and having a cross-sectional shape that is superior in rectangularity can be formed. Therefore, the composition for pattern formation and the pattern-forming method according to the embodiments of the present invention can be suitably used for lithography processes in manufacture of various types of electronic devices such as semiconductor devices and liquid crystal devices for which further miniaturization is demanded.

Obviously, numerous modifications and variations of the present invention are possible in light of the above teachings. It is therefore to be understood that within the scope of the appended claims, the invention may be practiced otherwise than as specifically described herein.

What is claimed is:

1. A composition for pattern formation comprising:
a polymer or a polymer set comprising a plurality of polymers, the polymer or the polymer set being capable of forming a phase separation structure through directed self-assembly, the polymer or at least one polymer in the polymer set comprising a crosslinkable group in a side chain thereof.

2. The composition according to claim 1, wherein the crosslinkable group is an oxiranyl group, an oxetanyl group, a tetrahydrofurfuryl group, a vinyl group, a vinyl ether group, or a combination thereof.

3. The composition according to claim 1, wherein the polymer is a block copolymer.

4. The composition according to claim 3, wherein the block copolymer is a diblock copolymer or a triblock copolymer.

5. The composition according to claim 3, wherein only one kind of block of the block copolymer comprises the crosslinkable group.

6. The composition according to claim 3, wherein the block copolymer comprises: a polystyrene block comprising a styrene unit; and a poly(meth)acrylate block comprising a (meth)acrylic acid ester unit.

7. The composition according to claim 6, wherein the polystyrene block comprises the crosslinkable group.

8. The composition according to claim 1, wherein the composition comprises the polymer set, and only one kind of polymer in the polymer set comprises the crosslinkable group.

9. The composition according to claim 8, wherein the polymer set comprises a styrene polymer and an acrylic polymer.

10. The composition according to claim 9, wherein the styrene polymer comprises the crosslinkable group.

11. The composition according to claim 1, further comprising an acid generator that generates an acid upon application of energy.

12. A pattern-forming method comprising:
providing a directed self-assembling film on a substrate using the composition according to claim 1, the directed self-assembling film comprising a phase separation structure.

13. The pattern-forming method according to claim 12, further comprising:
forming a prepattern on the substrate, wherein the directed self-assembling film is provided after forming the prepattern.

14. The pattern-forming method according to claim 12, wherein a line-and-space pattern or a hole pattern is formed.
